(19) United States
(12) Patent Application Publication
(10) Pub. No.: US 2026/0282366 A1
(43) Pub. Date: Sep. 17, 2026

(54) MEMORY DEVICE AND ELECTRONIC DEVICE

(71) Applicant: SEMICONDUCTOR ENERGY LABORATORY CO., LTD., Atsugi-shi, Kanagawa-ken (JP)

(72) Inventors: Kensuke YOSHIZUMI, Atsugi, Kanagawa (JP); Yoshiaki OIKAWA, Atsugi, Kanagawa (JP); Naoto KUSUMOTO, Isehara, Kanagawa (JP)

(21) Appl. No.: 19/168,866

(22) PCT Filed: Apr. 1, 2024
(86) PCT No.: PCT/IB2024/053142

§ 371 Date: Sep. 25, 2025

(30) Foreign Application Priority Data
Apr. 7, 2023 (JP) 2023-062489

(51) Int. Cl. H10B 43/35; H10B 43/27

(52) U.S. Cl. CPC H10B 43/35; H10B 43/27

(57) ABSTRACT

A memory device with few transistor manufacturing steps is provided. Each of a first selection transistor, a cell transistor, and a second selection transistor included in a memory string includes a cylindrical structure body. The structure body includes an oxide semiconductor, an insulator, and a conductor concentrically in an inward direction from a side surface. In the memory string, the transistors can be arranged in the lateral direction, and the first selection transistor and the second selection transistor can be formed in the same step. Accordingly, the number of transistor manufacturing steps can be reduced.

### TECHNICAL FIELD

One embodiment of the present invention relates to a memory device and an electronic device.

Note that one embodiment of the present invention is not limited to the above technical field. The technical field of the invention disclosed in this specification and the like relates to an object, a method, or a manufacturing method. One embodiment of the present invention relates to a process, a machine, manufacture, or a composition of matter. Therefore, specific examples of the technical field of one embodiment of the present invention disclosed in this specification include a semiconductor device, a display device, a liquid crystal display device, a light-emitting device, a power storage device, an imaging device, a memory device, a signal processing device, a processor, an electronic device, a system, a driving method thereof, a manufacturing method thereof, and a testing method thereof.

Note that in this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

One embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

NAND flash memories in which the degree of integration is increased by placing memory cells three-dimensionally have been widely used as large-capacity memory devices used in information terminals (Patent Document 1). In this specification and the like, a NAND flash memory in which memory cells are placed three-dimensionally is referred to as “3D NAND”.

Although polycrystalline silicon is used for a semiconductor layer of a transistor included in a memory string of the 3D NAND in many cases, Patent Document 2 discloses an example in which an oxide semiconductor is used for the semiconductor layer. Note that the memory string has a structure in which a plurality of memory cells are connected in series, and generally refers to a structure including a selection transistor.

### REFERENCES

### Patent Documents

[Patent Document 1] Japanese Published Patent Application No. 2007-266143
[Patent Document 2] Japanese Published Patent Application No. 2016-225614

### SUMMARY OF THE INVENTION

### Problems to be Solved by the Invention

The memory string of the 3D NAND has a structure in which a plurality of cell transistors connected in series are sandwiched between a selection transistor on a bit line side and a selection transistor on a source line side. In a general 3D NAND, the memory string is placed vertically; one of the selection transistors is provided at a lower end, and the other of the selection transistors is provided at an upper end.

The cell transistors can each be formed to have an area of 4F² (F is the minimum feature size), and the selection transistors are also preferably provided to have similar shapes so as not to degrade the degree of integration. Note that the selection transistor mainly has a switching function and thus has a structure different from that of the cell transistor having a memory function.

Therefore, in the structure in which the memory string is placed vertically, the following steps are used: forming the selection transistor at the lower end, forming the cell transistors thereover, and forming the selection transistor at the upper end thereover. In this manner, three transistor manufacturing steps are needed in the general 3D NAND.

Thus, an object of one embodiment of the present invention is to provide a memory device with few transistor manufacturing steps. Another object is to provide a memory device with large memory capacity. Another object is to provide a memory device with a high degree of integration. Another object is to provide a semiconductor device including the memory device. Another object is to provide a novel semiconductor device or the like.

Note that the objects of one embodiment of the present invention are not limited to the objects listed above. The objects listed above do not preclude the existence of other objects. Note that the other objects are objects that are not described in this section and will be described below. The objects that are not described in this section will be derived from the description of the specification, the drawings, and the like and can be extracted as appropriate from the description by those skilled in the art. Note that one embodiment of the present invention achieves at least one of the objects listed above and the other objects. Note that one embodiment of the present invention does not have to achieve all of the objects listed above and the other objects.

### Means for Solving the Problems

One embodiment of the present invention relates to a 3D NAND with few transistor manufacturing steps.

One embodiment of the present invention is a memory device including a memory string in which a first transistor, a plurality of second transistors, and a third transistor are connected in series in this order. The first to third transistors each include a cylindrical structure body. The structure body has a structure in which an oxide semiconductor, an insulator, and a first conductor are concentrically provided in this order in an inward direction from a side surface. The structure body includes a first region on the side surface and a second region on a side opposite to the first region. A second conductor is provided in contact with the first region and a third conductor is provided in contact with the second region. In the first to third transistors, the first conductor has a function of a gate electrode, the second conductor has a function of one of a source electrode and a drain electrode, and the third conductor has a function of the other of the source electrode and the drain electrode. The second transistor includes a charge accumulation layer between the oxide semiconductor and the first conductor.

One of a source and a drain of the first transistor is electrically connected to a source line, and one of a source and a drain of the third transistor is electrically connected to a bit line.

A memory block can be formed by stacking a plurality of memory strings in a direction perpendicular to a longitudinal direction of the memory string. The memory device can include a plurality of memory blocks.

Silicon nitride can be used for the charge accumulation layer. The oxide semiconductor preferably contains at least one of indium and zinc.

An electronic device including the memory device and at least one of a camera and a display portion is also one embodiment of the present invention.

### Effect of the Invention

According to one embodiment of the present invention, a memory device with few transistor manufacturing steps can be provided. Alternatively, a memory device with large memory capacity can be provided. Alternatively, a memory device with a high degree of integration can be provided. Alternatively, a semiconductor device including the memory device can be provided. Alternatively, a novel semiconductor device or the like can be provided.

Note that the effects of one embodiment of the present invention are not limited to the effects listed above. The effects listed above do not preclude the existence of other effects. Note that the other effects are effects that are not described in this section and will be described below. The effects that are not described in this section can be derived from the description of the specification, the drawings, and the like and can be extracted as appropriate from the description by those skilled in the art. Note that one embodiment of the present invention has at least one of the effects listed above and the other effects. Accordingly, one embodiment of the present invention sometimes does not have the effects listed above depending on the case.

### BRIEF DESCRIPTION OF THE DRAWINGS

FIG. 1A is a perspective view illustrating a memory string. FIG. 1B is a circuit diagram of the memory string.

FIG. 2 is a perspective view illustrating a memory block.

FIG. 3 is a cross-sectional view illustrating a memory block.

FIG. 4A to FIG. 4D are diagrams illustrating a manufacturing method of a memory block. FIG. 4E is a cross-sectional view illustrating a cell transistor. FIG. 4F is a cross-sectional view illustrating a selection transistor.

FIG. 5A is a diagram showing Id-Vg characteristics of a transistor. FIG. 5B is a timing chart showing operation of a memory string.

FIG. 6A to FIG. 6E are diagrams illustrating operations of a memory string.

FIG. 7A is a perspective view illustrating a memory device. FIG. 7B is a circuit diagram illustrating the memory device.

FIG. 8 is a block diagram illustrating a structure example of a semiconductor device.

FIG. 9 is a diagram illustrating a structure example of a semiconductor device.

FIG. 10 is a block diagram illustrating a CPU.

FIG. 11A and FIG. 11B are perspective views of a semiconductor device.

FIG. 12A and FIG. 12B are perspective views of a semiconductor device.

FIG. 13A and FIG. 13B are perspective views of a semiconductor device.

FIG. 14A and FIG. 14B are diagrams each showing a hierarchy of a variety of memory devices.

FIG. 15A and FIG. 15B are diagrams each illustrating an example of an electronic component.

FIG. 16A and FIG. 16B are diagrams each illustrating an example of an electronic device. FIG. 16C to FIG. 16E are diagrams illustrating an example of a large computer.

FIG. 17 is a diagram illustrating an example of a device for space.

FIG. 18 is a diagram illustrating an example of a storage system applicable to a data center.

### MODE FOR CARRYING OUT THE INVENTION

Embodiments will be described below with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the description of the embodiments below.

Furthermore, in the drawings, the same reference numerals are used in common for the same portions or portions having similar functions in different drawings, and repeated description thereof is omitted in some cases. The same hatching pattern is used for portions having similar functions, and the portions are not especially denoted by reference numerals in some cases.

In this specification and the like, an oxynitride is a material that contains more oxygen than nitrogen in its composition. Examples of the oxynitride include silicon oxynitride, aluminum oxynitride, and hafnium oxynitride. Moreover, a nitride oxide is a material that contains more nitrogen than oxygen in its composition. Examples of the nitride oxide include silicon nitride oxide, aluminum nitride oxide, and hafnium nitride oxide.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, the expression “parallel” indicates a state where two straight lines are placed at an angle greater than or equal to −10° and less than or equal to 10°. Accordingly, the case where the angle is greater than or equal to −5° and less than or equal to 5° is also included. Furthermore, the expression “substantially parallel” indicates a state where two straight lines are placed at an angle greater than or equal to −30° and less than or equal to 30°. Moreover, the expression “perpendicular” indicates a state where two straight lines are placed at an angle greater than or equal to 80° and less than or equal to 100°. Accordingly, the case where the angle is greater than or equal to 85° and less than or equal to 95° is also included. Furthermore, the expression “substantially perpendicular” indicates a state where two straight lines are placed at an angle greater than or equal to 60° and less than or equal to 120°. The term “orthogonal” indicates a state where two straight lines intersect or are connected to each other at an angle greater than or equal to 80° and less than or equal to 100°. Thus, the case where the angle is greater than or equal to 85° and less than or equal to 95° is also included. The terms “approximately orthogonal” and “substantially orthogonal” each indicate a state where two straight lines intersect or are connected to each other at an angle greater than or equal to 60° and less than or equal to 120°.

In the drawings and the like for this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. The X direction, the Y direction, and the Z direction are directions orthogonal to each other.

Moreover, in this specification and the like, terms for describing placement, such as “over” and “under”, are used for convenience for describing the positional relationship between components with reference to drawings. The positional relationship between components is changed as appropriate in accordance with the direction in which each component is described. Thus, without limitation to terms described in this specification, the description can be changed appropriately depending on the situation.

### Embodiment 1

In this embodiment, a memory device of one embodiment of the present invention will be described.

One embodiment of the present invention is a 3D NAND memory device including an oxide semiconductor in a semiconductor layer. A memory string included in the memory device has a structure in which a first selection transistor, a plurality of cell transistors, and a second selection transistor are connected in series in this order. Note that in this specification, the 3D NAND memory device including an oxide semiconductor is referred to as a 3D OS NAND (registered trademark) in some cases.

Each of the first selection transistor, the cell transistors, and the second selection transistor includes a cylindrical structure body. The structure body includes an oxide semiconductor, an insulator, and a first conductor concentrically in an inward direction from a side surface, and a second conductor and a third conductor are provided in contact with the side surface of the structure body. The first conductor functions as a gate electrode, one of the second conductor and the third conductor functions as a source electrode, and the other functions as a drain electrode.

In the cell transistor, a charge accumulation layer is further provided between the oxide semiconductor and the first conductor. Thus, the cell transistor and the selection transistor are formed in different steps. A memory string used in a general 3D NAND is placed vertically with the longitudinal direction regarded as the height direction, and the first selection transistor, the cell transistor, and the second selection transistor are separately formed in different steps; thus, three transistor manufacturing steps are needed.

Meanwhile, in the memory string of one embodiment of the present invention, the transistors can be arranged in the lateral direction, and the first selection transistor and the second selection transistor can be formed in the same step. Thus, the number of transistor manufacturing steps can be reduced to two, which leads to a reduction in manufacturing cost.

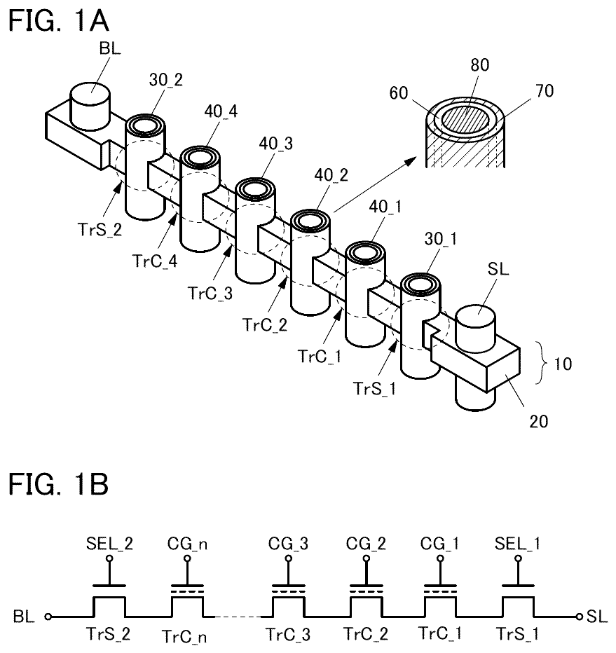

FIG. 1A includes a perspective view of a memory string of one embodiment of the present invention and an enlarged view of part of the memory string. Note that an insulating layer such as an interlayer film is not illustrated. FIG. 1B is a circuit diagram of the memory string. A memory string 10 has a structure in which a selection transistor TrS_1, a plurality of cell transistors TrC (cell transistors TrC_1 to TrC_4), and a selection transistor TrS_2 are arranged in a line in the lateral direction and connected in series in this order. The cell transistor TrC can operate as a memory cell alone. Thus, the memory string 10 functions as a NAND memory device including a plurality of memory cells.

Although an example in which four cell transistors TrC are connected in series is illustrated in FIG. 1A, n cell transistors TrC may be connected in series as illustrated in the circuit diagram in FIG. 1B. Note that n is an integer greater than or equal to 4, and can be 100, 200, or more, for example. As the value of n becomes larger, the memory capacity can be increased.

The selection transistor TrS_1 and the selection transistor TrS_2 include structure bodies 30 (structure bodies 30_1 and 30_2), and the cell transistors TrC include structure bodies 40 (structure bodies 40_1 to 40_4).

The structure body 30 and the structure body 40 each have a structure in which an oxide semiconductor 70, an insulator 60, and a conductor 80 are concentrically provided in this order in an inward direction from a side surface, and a pair of conductors 20 are provided in contact with each of the side surfaces of the structure body 30 and the structure body 40. The width of the conductor 20 is smaller than the diameter of each of the structure body 30 and the structure body 40, one of the conductors 20 is provided in contact with a first region included in the side surface of the structure body 30 or the structure body 40, and the other of the conductors 20 is provided in contact with a second region on a side opposite to the first region. Although the details will be described later, the structure of the insulator 60 differs between the structure body 30 and the structure body 40, and the structure body 40 includes a charge accumulation layer in the insulator 60.

The conductor 80 functions as a gate electrode, one of the conductors 20 functions as one of a source electrode and a drain electrode, and the other of the conductors 20 functions as the other of the source electrode and the drain electrode. Note that the conductor 20 is shared by adjacent transistors. The shared conductor 20 functions as the source electrode of one of the transistors and functions as the drain electrode of the other of the transistors.

One of the pair of conductors 20 provided in contact with the side surface of the structure body 30_1 is electrically connected to a source line SL. That is, as illustrated in FIG. 1B, one of a source and a drain of the selection transistor TrS_1 is electrically connected to the source line SL. One of the pair of conductors 20 provided in contact with the side surface of the structure body 30_2 is electrically connected to a bit line BL. That is, as illustrated in FIG. 1B, one of a source and a drain of the selection transistor TrS_2 is electrically connected to the bit line BL.

As illustrated in FIG. 1B, a wiring SEL_1 is electrically connected to a gate of the selection transistor TrS_1, and a wiring SEL_2 is electrically connected to a gate of the selection transistor TrS_2. The wiring SEL_1 and the wiring SEL_2 are wirings supplying a signal potential for selecting one memory string 10 in data resetting, writing, and reading.

Wirings CG (wirings CG_1 to CG_n) are electrically connected to gates of the cell transistors TrC. The wiring CG is a wiring supplying a signal potential for selecting one cell transistor TrC in data resetting, writing, and reading.

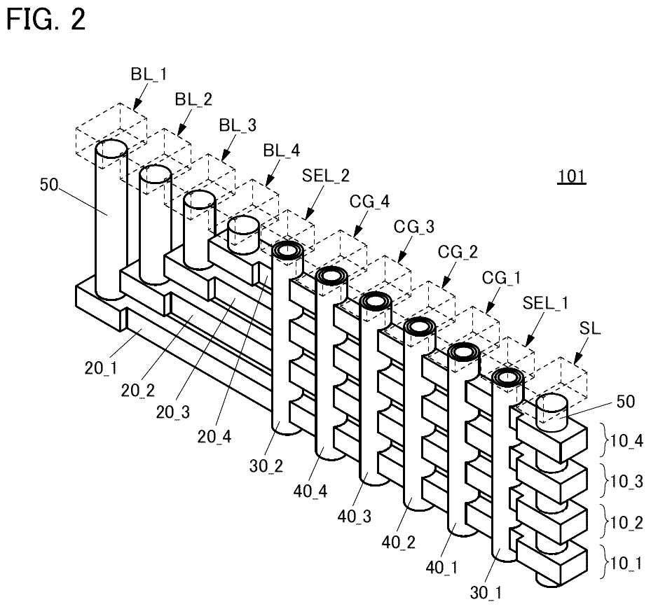

FIG. 2 is a perspective view illustrating a memory block 101 in which the memory strings 10 are stacked in the vertical direction (the direction perpendicular to the longitudinal direction of the memory string 10). Note that an insulating layer such as an interlayer film is not illustrated. The source line SL, the wiring SEL_1, the wirings CG, the wiring SEL_2, and the bit lines BL (bit lines BL_1 to BL_4) which are illustrated in the uppermost portion are indicated by dashed lines for clarity. The wiring SEL_1, the wirings CG, and the wiring SEL_2 are each electrically connected to the above-described conductor 80. Note that the conductor 80 may be part of each wiring.

Although the memory block 101 illustrated in FIG. 2 has a structure in which four memory strings 10 (memory strings 10_1 to 10_4) are stacked, the structure is not limited thereto. A stacked-layer structure of 100 or more memory strings 10 or 200 or more memory strings 10 can be employed. As the number of stacked memory strings 10 increases, the memory capacity can be increased.

Note that although the expression “the memory strings 10 are stacked in the vertical direction” is used in the above description, the memory strings 10 share the structure body 30 and the structure body 40. Thus, after the insulators and the conductors 20 (conductors 20_1 to 20_4) are alternately stacked, the structure body 30 or the structure body 40 is formed in a position where the conductor 20 is divided, whereby a plurality of transistors can be formed in the height direction using the same material in the same step. Furthermore, there is no need to separate the structure body between upper and lower memory strings, so that the degree of integration can be increased.

In the memory block 101, the memory strings 10 are operated in parallel, so that the wiring SEL_1, the wiring CG, the wiring SEL_2, and the source line SL can be shared. Note that since the memory strings 10 handle different data, the bit line BL is provided for each memory string 10.

As illustrated in FIG. 2, the memory string 10_1 can be electrically connected to the bit line BL_1 through the conductor 20_1 and a plug 50. The memory string 10_2 can be electrically connected to the bit line BL_2 through the conductor 20_2 and the plug 50. The memory string 10_3 can be electrically connected to the bit line BL_3 through the conductor 20_3 and the plug 50. The memory string 10_4 can be electrically connected to the bit line BL_4 through the conductor 20_4 and the plug 50. In the memory strings 10_1 to 10_4, the conductors 20_1 to 20_4 can be electrically connected to the source line SL through the plug 50.

Note that in the above structure, the conductors 20_1 to 20_4 may be referred to as local bit lines, and the bit lines BL_1 to BL_4 may be referred to as global bit lines.

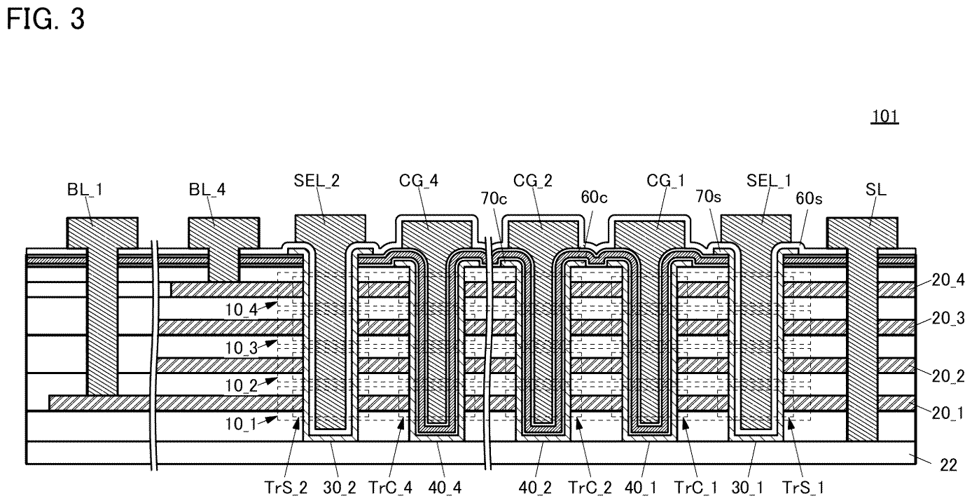

FIG. 3 is a diagram corresponding to a cross section of the memory block 101 illustrated in FIG. 2. Although each of the source line SL and the bit line BL is integrally formed with a plug portion in the illustrated example, the plug and the wiring can be separately formed as illustrated in FIG. 2. Furthermore, although the conductor 80 is formed as part of the wiring (any of the wirings CG_1 to CG_4, the wiring SEL_1, and the wiring SEL_2) also in the structure body 30 and the structure body 40, the conductor 80 and the wiring can be separately formed. Note that the oxide semiconductor 70 and the insulator 60 provided in the structure body 30 are illustrated as an oxide semiconductor 70s and an insulator 60s, respectively. The oxide semiconductor 70 and the insulator 60 provided in the structure body 40 are illustrated as an oxide semiconductor 70c and an insulator 60c, respectively.

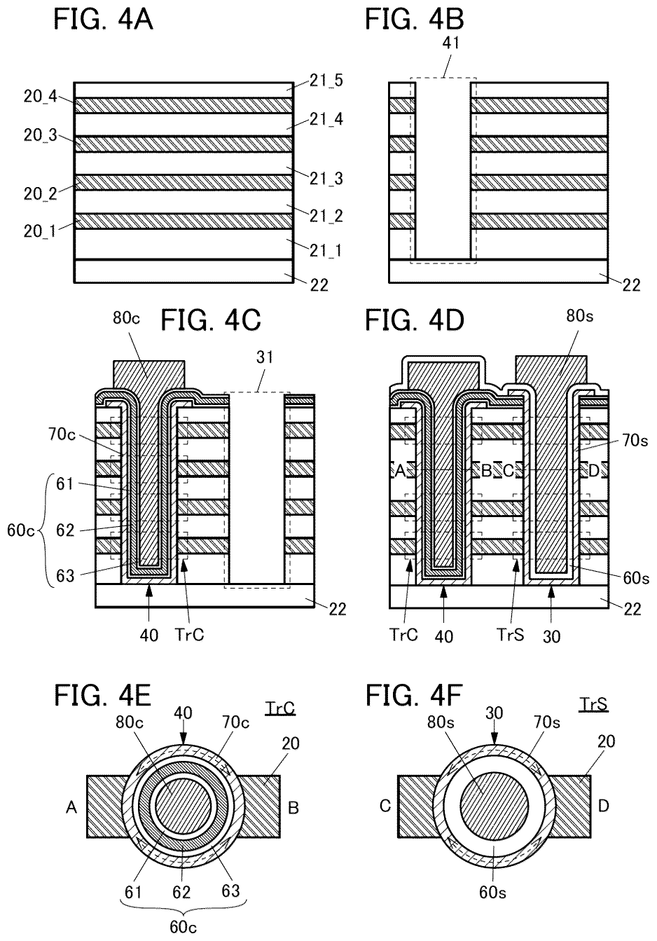

FIG. 4A to FIG. 4D are diagrams illustrating a method for manufacturing the cell transistor TrC and the selection transistor TrS illustrated in FIG. 3. First, a stack in which insulators 21 (insulators 21_1 to 21_5) and the conductors 20 (the conductors 20_1 to 20_4) are alternately formed is formed over an insulator 22 (see FIG. 4A).

Next, to form the structure body 40, an opening portion 41 having a circular shape in the top view and reaching the insulator 22 is formed (see FIG. 4B).

Next, the oxide semiconductor 70c is formed to cover the side surface and the bottom surface of the opening portion 41, and the insulator 60c including a charge accumulation layer is formed over the oxide semiconductor 70c. Next, a conductor 80c is formed over the insulator 60c to fill the opening portion 41 (see FIG. 4C). Here, a plurality of cell transistors TrC illustrated in FIG. 3 are completed.

Next, to form the structure body 30, an opening portion 31 having a circular shape in the top view and reaching the insulator 22 is formed (see FIG. 4C). Note that the diameters of the opening portion 41 and the opening portion 31 are the same in the illustrated example, but can be set as appropriate without limitation to this.

Next, the oxide semiconductor 70s is formed to cover the side surface and the bottom surface of the opening portion 41, and the insulator 60s is formed over the oxide semiconductor 70s. Note that the oxide semiconductor 70s may be formed using the same material as the oxide semiconductor 70c. Next, a conductor 80s is formed over the insulator 60s to fill the opening portion 31 (see FIG. 4D). Here, the selection transistors TrS_1 and TrS_2 illustrated in FIG. 3 are completed.

Next, an opening portion for forming the source line SL and the bit line BL is formed, and the source line SL and the bit line BL are formed to fill the opening portion (see FIG. 3).

As described above, in one embodiment of the present invention, the selection transistors TrS_1 and TrS_2 can be manufactured in the same step; thus, the number of transistor manufacturing steps can be smaller than the number of transistor manufacturing steps in a conventional 3D NAND. Although the structure body 30 is formed after the structure body 40 is formed in the above-described example, the structure body 40 may be formed after the structure body 30 is formed.

FIG. 4E is a cross-sectional view of the cell transistor TrC at the A-B position illustrated in FIG. 4D.

The cell transistor TrC includes the oxide semiconductor 70c on the side surface (outermost periphery) of the structure body 40, includes the insulator 60c on the inner side thereof, and includes the conductor 80c on the inner side thereof. The oxide semiconductor 70c, the insulator 60c, and the conductor 80c are provided concentrically. One of the conductors 20 is provided in contact with a first region that is part of the side surface of the oxide semiconductor 70c, and the other of the conductors 20 is provided in contact with a second region on a side opposite to the first region. One of the conductors 20 functions as a source electrode and the other of the conductors 20 functions as a drain electrode.

The conductor 20 is provided to have a width smaller than the diameter of the structure body 40. Thus, a region of the oxide semiconductor 70c that is in contact with one of the conductors 20 functions as one of a source and a drain, and a region of the oxide semiconductor 70c that is in contact with the other of the conductors 20 functions as the other of the source and the drain. A region of the oxide semiconductor 70c that is not in contact with one or the other of the conductors 20 between one and the other of the conductors 20 functions as a channel formation region.

Since the oxide semiconductor 70c has a ring shape, there are two channel formation regions between one and the other of the conductors 20. The channel length of the cell transistor TrC corresponds to the distance along the circumference of the oxide semiconductor 70c between one and the other of the conductors 20 (see a dashed arrow in the drawing), and the channel width corresponds to the thickness of the conductor 20.

The channel length can be controlled by the diameter of the structure body 40 (the diameter of the opening portion 41). In the case where the channel length is desired to be large, for example, the diameter of the structure body 40 is set large. Alternatively, the channel length can be controlled by the width of the conductor 20. Although the example where the opening portion has a circular shape in the top view is described, one embodiment of the present invention is not limited thereto. For example, the opening portion can have an elliptical shape or a polygonal shape with rounded corners besides the circular shape in the top view. Note that the circular shape is not limited to a perfect circle.

The insulator 60c functions as a gate insulator and a memory region. The conductor 80c functions as a gate electrode. That is, the conductor 80c functions as a control gate of a memory cell. An insulator 61 included in the insulator 60c functions as a block layer, an insulator 62 functions as a charge accumulation layer, and an insulator 63 functions as a tunnel layer. When a high voltage is applied to the conductor 80c, electrons can be injected from the oxide semiconductor 70c into the insulator 62 through the insulator 63.

As illustrated in FIG. 1B, a gate of the cell transistor TrC is electrically connected to the wiring CG. That is, the conductor 80c is electrically connected to the wiring CG. Alternatively, as illustrated in FIG. 3, the conductor 80c may be formed as part of the wiring CG. The wiring CG can be also referred to as a “control gate” or a “control gate wiring”.

A material whose bandgap is smaller than those of the insulator 61 and the insulator 63 is used for the insulator 62 that functions as the charge accumulation layer. The thickness of the insulator 63 (the length in the direction perpendicular to the Z direction) is preferably greater than or equal to 1 nm and less than or equal to 10 nm. The thickness of the insulator 62 is preferably greater than or equal to 5 nm and less than or equal to 20 nm. The thickness of the insulator 61 is preferably greater than or equal to 5 nm and less than or equal to 50 nm. In addition, the thickness of the insulator 63 is preferably smaller than that of the insulator 61. When the thicknesses of the insulator 62 and the insulator 63 are in the above range, electrons can be efficiently transferred into and from the charge accumulation layer.

For example, silicon oxide can be used for the insulator 61 and the insulator 63, and silicon nitride can be used for the insulator 62. The insulators 61 to 63 can each have a stacked-layer structure of a plurality of insulators. For example, the insulator 63 can have a stacked-layer structure of silicon oxide and aluminum oxide. When the insulator 63 has a stacked-layer structure, the reliability of the cell transistor TrC can be increased.

For example, silicon nitride can be used for the insulator 61 and the insulator 63. In that case, when silicon nitride having a higher silicon content than silicon nitride used for the insulator 61 and the insulator 63 is used for the insulator 62, the insulator 62 can function as the charge accumulation layer.

FIG. 4F is a cross-sectional view of the selection transistor TrS at the C-D position illustrated in FIG. 4D. The selection transistor TrS is different from the cell transistor TrC in not including a charge accumulation layer.

The selection transistor TrS includes the oxide semiconductor 70s on the side surface (outermost periphery) of the structure body 30, includes the insulator 60s on the inner side thereof, and includes the conductor 80s on the inner side thereof. The oxide semiconductor 70s, the insulator 60s, and the conductor 80s are provided concentrically. One of the conductors 20 is provided in contact with a first region that is part of the side surface of the oxide semiconductor 70s, and the other of the conductors 20 is provided in contact with a second region on a side opposite to the first region. One of the conductors 20 functions as a source electrode and the other of the conductors 20 functions as a drain electrode.

The insulator 60s functions as a gate insulator. For example, silicon oxide can be used for the insulator 60s. The conductor 80s functions as a gate electrode.

The cell transistor TrC and the selection transistor TrS are each a transistor using an oxide semiconductor (an oxide semiconductor 70c or 70s), which is a kind of metal oxide, for a semiconductor layer where a channel is formed (also referred to as an “OS transistor”). An oxide semiconductor has a band gap of 2 eV or more, achieving an extremely low off-state current. Thus, the power consumption of the memory string 10 can be reduced. Accordingly, the power consumption of a memory device including the memory string 10 can be reduced.

A memory cell including an OS transistor can be referred to as an “OS memory”. Furthermore, the memory string 10 including the memory cell can also be referred to as an “OS memory”.

A transistor using polycrystalline silicon has variation in the threshold voltage caused by a crystal grain boundary, whereas the OS transistor has little influence by a crystal grain boundary and small variation in the threshold voltage. Accordingly, when the OS transistor is used as the cell transistor TrC, malfunction caused by variation in the threshold voltage can be suppressed in the memory string 10.

The OS transistor operates stably even in a high-temperature environment and has small change in characteristics. For example, the off-state current hardly increases even in a high-temperature environment. Specifically, the off-state current hardly increases even at an environmental temperature higher than or equal to room temperature and lower than or equal to 200° C. Furthermore, the on-state current of the OS transistor is unlikely to decrease even in the high-temperature environment. Thus, the memory string 10 including the OS memory achieves stable operation and high reliability even in the high-temperature environment. Furthermore, the OS transistor has high withstand voltage between its source and drain. When the OS transistor is used as a transistor included in the memory string 10, it is possible to achieve the memory string that operates stably and has high reliability even in the high-temperature environment. Accordingly, the reliability of the memory device including the memory string 10 can be increased.

Component materials that can be used for the memory device are described below.

### [Substrate]

As a substrate where the memory string 10 is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the above-described semiconductor substrate, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided over the substrate include a capacitor, a resistor, a switching element, a light-emitting element, and a memory element.

### [Insulator]

Examples of an insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors proceed, for example, a problem such as leakage current may arise because of a thinner gate insulator. When a high-k material is used for an insulator functioning as a gate insulator, the voltage at the time of the operation of the transistor can be reduced while the physical thickness is maintained. In addition, the equivalent oxide thickness (EOT) of the insulator functioning as the gate insulator can be reduced. In contrast, when a material with a low dielectric constant is used for an insulator functioning as an interlayer film, the capacity of parasitic capacitance generated between wirings can be reduced. Thus, a material is preferably selected in accordance with the function of the insulator. Note that the material with a low dielectric constant is a material with high dielectric strength.

Examples of the material with a high dielectric constant (high-k material) include aluminum oxide, gallium oxide, hafnium oxide, tantalum oxide, zirconium oxide, a hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with a low dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of the inorganic insulating material with a low dielectric constant include silicon oxide to which fluorine is added, silicon oxide to which carbon is added, and silicon oxide to which carbon and nitrogen are added. Another example is porous silicon oxide. These silicon oxides may contain nitrogen.

When a transistor including a metal oxide (oxide semiconductor) is surrounded by an insulator having a function of inhibiting passage of impurities and oxygen, the transistor can have stable electrical characteristics. As the insulator having a function of inhibiting passage of impurities and oxygen, a single layer or stacked layers of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used, for example. Specifically, as the insulator having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor or provided in the vicinity of a semiconductor layer, such as a gate insulator, preferably includes a region containing excess oxygen. For example, when an insulator including a region containing excess oxygen is in contact with a semiconductor layer or provided in the vicinity of the semiconductor layer, oxygen vacancies in the semiconductor layer can be reduced. Examples of an insulator in which a region containing excess oxygen is easily formed include silicon oxide, silicon oxynitride, and porous silicon oxide.

Examples of an insulator having a barrier property against oxygen include an oxide containing one or both of aluminum and hafnium, an oxide containing hafnium and silicon (hafnium silicate), magnesium oxide, gallium oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of an insulator having a barrier property against hydrogen include aluminum oxide, magnesium oxide, hafnium oxide, gallium oxide, silicon nitride, and silicon nitride oxide.

The insulator having a barrier property against oxygen and the insulator having a barrier property against hydrogen can each be regarded as an insulator having a barrier property against one or both of oxygen and hydrogen.

Examples of the insulator having a function of capturing or fixing hydrogen include an oxide containing magnesium and an oxide containing one or both of aluminum and hafnium. These oxides preferably have an amorphous structure. In an oxide having an amorphous structure, an oxygen atom has a dangling bond and sometimes has a property of capturing or fixing hydrogen with the dangling bond. Note that such an oxide preferably has an amorphous structure, but a crystal region may be partly formed.

In this specification and the like, a barrier insulating film refers to an insulating film having a barrier property. The barrier property refers to a property that does not easily allow diffusion of a target substance (also referred to as a property that does not easily allow passage of a target substance, a property with low permeability to a target substance, or a function of inhibiting diffusion of a target substance). Note that a function of capturing or fixing (also referred to as gettering) a target substance can be rephrased as a barrier property. Note that hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule. Specifically, a barrier property against oxygen refers to a property that does not easily allow diffusion of at least one of an oxygen atom, an oxygen molecule, and the like.

### [Conductor]

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above-described metal elements; an alloy containing a combination of the above-described metal elements; or the like. As the alloy containing any of the above-described metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Alternatively, a semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include an indium oxide containing tungsten oxide, an indium oxide containing titanium oxide, an indium tin oxide, an indium tin oxide containing titanium oxide, an indium tin oxide to which silicon is added, an indium zinc oxide, and an indium zinc oxide containing tungsten oxide. In this specification and the like, a conductive film formed using the conductive material containing oxygen may be referred to as an oxide conductive film.

A conductive material containing tungsten, copper, or aluminum as its main component is preferable because it has high conductivity.

A stack of a plurality of conductive layers formed of the above materials can be used. For example, a stacked-layer structure combining a material containing the above-described metal element and a conductive material containing oxygen can be used. Alternatively, a stacked-layer structure combining a material containing the above-described metal element and a conductive material containing nitrogen can be used. Alternatively, a stacked-layer structure combining a material containing the above-described metal element, a conductive material containing oxygen, and a conductive material containing nitrogen can be used.

In the case where a metal oxide is used for a channel formation region of a transistor, a conductor functioning as a gate electrode preferably has a stacked-layer structure combining a material containing the above-described metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in a metal oxide where a channel is formed. A conductive material containing the above-described metal element and nitrogen may be used. For example, a conductive material containing nitrogen, such as titanium nitride or tantalum nitride, may be used. One or more of an indium tin oxide, an indium oxide containing tungsten oxide, an indium zinc oxide containing tungsten oxide, an indium oxide containing titanium oxide, an indium tin oxide containing titanium oxide, an indium zinc oxide, and an indium tin oxide to which silicon is added may be used. An indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### [Metal Oxide (Oxide Semiconductor)]

Structures of metal oxides are classified into a single crystal structure and other structures (non-single-crystal structures). Examples of non-single-crystal structures include a CAAC structure, a polycrystalline structure, an nc structure, an amorphous-like (a-like) structure, and an amorphous structure. An a-like structure has a structure between an nc structure and an amorphous structure. Note that the classification of crystal structures will be described later.

A metal oxide having an a-like structure and a metal oxide having an amorphous structure each include a void or a low-density region. That is, a metal oxide having an a-like structure and a metal oxide having an amorphous structure have low crystallinity as compared with a metal oxide having an nc structure and a metal oxide having a CAAC structure. Moreover, a metal oxide having an a-like structure has a higher hydrogen concentration in the metal oxide than a metal oxide having an nc structure and a metal oxide having a CAAC structure. Thus, a lattice defect is easily formed in a metal oxide having an a-like structure and a metal oxide having an amorphous structure.

Therefore, a metal oxide with high crystallinity is preferably used for a semiconductor layer of a transistor. For example, a metal oxide having a CAAC structure or a metal oxide having a single crystal structure is preferably used. The use of the metal oxide for a transistor enables the transistor to have favorable electrical characteristics. In addition, a transistor with high reliability can be achieved.

For a channel formation region of a transistor, a metal oxide that increases the on-state current of the transistor is preferably used. To increase the on-state current of the transistor, the mobility of the metal oxide used for the transistor is preferably increased. To increase the mobility of the metal oxide, the transfer of carriers (electrons in the case of an n-channel transistor) needs to be facilitated or scattering factors that affect the transfer of carriers need to be reduced. Note that the carriers flow from a source to a drain through the channel formation region. Hence, the on-state current of the transistor can be increased by providing the channel formation region through which carriers can easily flow in the channel length direction.

Here, it is preferable to use a metal oxide with high crystallinity for a metal oxide including a channel formation region. The crystal preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which a plurality of layers are stacked. Examples of a metal oxide including the crystal include a single crystal oxide semiconductor and a CAAC-OS (c-axis aligned crystalline oxide semiconductor).

The c-axis of the above crystal is preferably aligned in the normal direction with respect to the formation surface or film surface of the metal oxide. This enables a plurality of layers to be placed parallel or substantially parallel to the formation surface or film surface of the metal oxide. In other words, a plurality of layers extend in the channel length direction.

The above three-layer crystal structure is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal include a YbFe₂O₄ type structure, a Yb₂Fe₃O₇ type structure, and their deformed structures.

Each of the first layer to the third layer is preferably composed of oxygen and one metal element or a plurality of metal elements with the same valence. The valence of the one or plurality of metal elements included in the first layer is preferably equal to the valence of the one or plurality of metal elements included in the second layer. The first layer and the second layer may include the same metal element. The valence of the one or plurality of metal elements included in the first layer is preferably different from the valence of the one or plurality of metal elements included in the third layer.

The above structure can increase the crystallinity of the metal oxide, which leads to an increase in the mobility of the metal oxide. Thus, the use of the metal oxide for the channel formation region of the transistor increases the on-state current of the transistor, leading to an improvement in the electrical characteristics of the transistor.

Examples of the metal oxide of one embodiment of the present invention include an indium oxide, a gallium oxide, and a zinc oxide. The metal oxide of one embodiment of the present invention preferably contains at least indium (In) or zinc (Zn). The metal oxide preferably contains two or three kinds selected from indium, an element M, and zinc. The element M is a metal element or a metalloid element that has a high binding energy with oxygen, such as a metal element or a metalloid element whose binding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. When the element M contained in the metal oxide is gallium, the metal oxide of one embodiment of the present invention preferably contains one or more selected from indium, gallium, and zinc. In this specification and the like, a metal element and a metalloid element may be collectively referred to as a “metal element”, and a “metal element” in this specification and the like may refer to a metalloid element.

For example, as the metal oxide semiconductor of one embodiment of the present invention, an indium zinc oxide (In—Zn oxide), an indium tin oxide (In—Sn oxide), an indium titanium oxide (In—Ti oxide), an indium gallium oxide (In—Ga oxide), an indium gallium aluminum oxide (In—Ga—Al oxide), an indium gallium tin oxide (In—Ga—Sn oxide), a gallium zinc oxide (Ga—Zn oxide, also referred to as GZO), an aluminum zinc oxide (Al—Zn oxide, also referred to as AZO), an indium aluminum zinc oxide (In—Al—Zn oxide, also referred to as IAZO), an indium tin zinc oxide (In—Sn—Zn oxide), an indium titanium zinc oxide (In—Ti—Zn oxide), an indium gallium zinc oxide (In—Ga—Zn oxide, also referred to as IGZO), an indium gallium tin zinc oxide (In—Ga—Sn—Zn oxide, also referred to as IGZTO), or an indium gallium aluminum zinc oxide (In—Ga—Al—Zn oxide, also referred to as IGAZO or IAGZO) can be used. Alternatively, an indium tin oxide containing silicon, a gallium tin oxide (Ga—Sn oxide), an aluminum tin oxide (Al—Sn oxide), or the like can be given as an example.

By increasing the proportion of the number of indium atoms in the total number of atoms of all the metal elements contained in the metal oxide, the field-effect mobility of the transistor can be increased.

Note that the metal oxide may contain, instead of indium, one or more kinds of metal elements with large period numbers. Alternatively, the metal oxide may contain, in addition to indium, one or more kinds of metal elements with large period numbers. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be increased.

By increasing the proportion of the number of element M atoms in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be increased.

By increasing the proportion of the number of In atoms in the total number of atoms of all the metal elements contained in the metal oxide, a high on-state current and high frequency characteristics of the transistor can be achieved.

In the description of this embodiment, an In—Ga—Zn oxide is sometimes taken as an example of the metal oxide.

For the formation of a metal oxide having the layered crystal structure, an atomic layer is preferably deposited one by one. Since an ALD method is used as the film formation method of the metal oxide of one embodiment of the present invention, a metal oxide having the layered crystal structure is easily formed.

Examples of the ALD method include a thermal ALD method, in which a precursor and a reactant react with each other only by thermal energy, and a plasma ALD (PEALD: Plasma Enhanced ALD) method, in which a reactant excited by plasma is used.

In an ALD method, atomic layers can be deposited one by one. Hence, an ALD method has effects such as formation of an extremely thin film, formation of a film on a structure with a high aspect ratio, formation of a film with a small number of defects such as pinholes, formation of a film with excellent coverage, and formation of a film at a low temperature. The use of plasma in a PEALD method is sometimes preferable because it enables film formation at a lower temperature. Note that some precursors used in an ALD method contain an element such as carbon or chlorine. Thus, in some cases, a film provided by an ALD method contains a larger amount of an element such as carbon or chlorine than a film provided by another film formation method. Note that these elements can be quantified by XPS or SIMS. The film formation method of the metal oxide of one embodiment of the present invention, which employs an ALD method and one or both of a film formation condition with a high substrate temperature and impurity removal treatment, can sometimes form a film with smaller amounts of carbon and chlorine than a method employing an ALD method without the film formation condition with a high substrate temperature or the impurity removal treatment.

Unlike a film formation method in which particles ejected from a target or the like are deposited, an ALD method is a film formation method in which a film is formed by reaction at a surface of an object. Thus, an ALD method is a film formation method that enables favorable step coverage almost regardless of the shape of an object. In particular, an ALD method enables excellent step coverage and excellent thickness uniformity and thus is suitable for covering a surface of an opening portion with a high aspect ratio, for example. On the other hand, an ALD method has a relatively low film formation rate, and thus is preferably used in combination with another film formation method with a high film formation rate, such as a sputtering method or a CVD method, in some cases. A method in which a sputtering method is used to form a first metal oxide and an ALD method is used to form a second metal oxide over the first metal oxide is given as an example. For example, in the case where the first metal oxide has a crystal part, crystal growth occurs in the second metal oxide with the use of the crystal part as a nucleus.

In an ALD method, the composition of a film to be formed can be controlled with the amount of introduced source gas. For example, a film with a certain composition can be formed in an ALD method by adjusting the amount of introduced source gas, the number of times of introduction (also referred to as the number of pulses), the time required for one pulse (also referred to as the pulse time), and the like. Moreover, a film with a continuously changed composition can be formed in an ALD method by, for example, changing the source gas during deposition. In the case where the film is formed while the source gas is changed, as compared to the case where the film is formed using a plurality of deposition chambers, the time taken for the deposition can be shortened because the time taken for transfer and pressure adjustment is omitted. Thus, the productivity of the memory device can be increased in some cases.

A metal oxide sometimes includes a lattice defect. Examples of a lattice defect include point defects such as an atomic vacancy and an exotic atom, a line defect such as dislocation, a plane defect such as a crystal grain boundary, and a volume defect such as a void. Examples of a factor in generating the lattice defect include deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with a large number of lattice defects for a semiconductor layer of a transistor may cause unstable electrical characteristics of the transistor. Hence, a metal oxide used for a semiconductor layer of a transistor preferably has a small number of lattice defects.

In particular, the electrical characteristics of a transistor including a metal oxide easily vary when oxygen vacancies (Vo) and impurities exist in a channel formation region in the metal oxide, which might degrade the reliability. In some cases, a defect (hereinafter sometimes referred to as VoH) that is an oxygen vacancy into which hydrogen in the vicinity of the oxygen vacancy has entered is formed, which generates an electron serving as a carrier. Thus, when the channel formation region in the metal oxide includes oxygen vacancies, the transistor is likely to have normally-on characteristics. Accordingly, oxygen vacancies and impurities are preferably reduced as much as possible in the channel formation region of the metal oxide. In other words, the channel formation region in the metal oxide is preferably an i-type (intrinsic) or substantially i-type region with a reduced carrier concentration.

The kind of a lattice defect that is likely to exist in a metal oxide and the number of lattice defects that exist vary depending on the structure of the metal oxide, a film formation method of the metal oxide, or the like.

### [[Transistor Including Metal Oxide (Oxide Semiconductor)]]

Next, the case where a metal oxide (oxide semiconductor) is used for a transistor will be described. Hereinafter, a transistor including an oxide semiconductor in a semiconductor layer is sometimes referred to as an OS transistor, and a transistor including silicon in a semiconductor layer is sometimes referred to as a Si transistor.

When a metal oxide (oxide semiconductor) of one embodiment of the present invention is used for a transistor, a transistor with high field-effect mobility can be achieved. In addition, a transistor with high reliability can be achieved. Furthermore, a miniaturized or highly integrated transistor can be achieved. For example, a transistor with a channel length greater than or equal to 2 nm and less than or equal to 30 nm can be fabricated.

An oxide semiconductor with a low carrier concentration is preferably used for a channel formation region of a transistor. For example, the carrier concentration in the channel formation region of the oxide semiconductor is lower than or equal to 1×10¹⁸ cm⁻³, preferably lower than or equal to 1×10¹⁷ cm⁻³, further preferably lower than or equal to 1×10¹⁵ cm⁻³, still further preferably lower than or equal to 1×10¹³ cm⁻³, yet further preferably lower than or equal to 1×10¹¹ cm⁻³, yet still further preferably lower than 1×10¹⁰ cm⁻³, and higher than or equal to 1×10⁻⁹ cm⁻³. In order to reduce the carrier concentration in the oxide semiconductor, the impurity concentration in the oxide semiconductor is reduced so that the density of defect states is reduced. In this specification and the like, a state with a low impurity concentration and a low density of defect states is referred to as a highly purified intrinsic or substantially highly purified intrinsic state. Note that an oxide semiconductor with a low carrier concentration is sometimes referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, carbon, and nitrogen. Note that an impurity in an oxide semiconductor refers to, for example, elements other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a large band gap, and thus can suppress the short-channel effect. In other words, the OS transistor is a transistor in which the short-channel effect does not appear or hardly appears.

Note that the short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes referred to as an S value), and an increase in leakage current. Here, the S value means the amount of change in gate voltage which makes the drain current change by one digit in a subthreshold region at a constant drain voltage.

The characteristic length is widely used as an indicator of resistance to the short-channel effect. The characteristic length is an indicator of curving of potential in a channel formation region. When the characteristic length is shorter, the potential rises more sharply, which means that the resistance to the short-channel effect is high.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to the short-channel effect than the Si transistor. That is, in the case where a transistor with a short channel length is to be fabricated, the OS transistor is more suitable than the Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region become n⁺-type regions.

The OS transistor with the above structure can have favorable electrical characteristics even when a memory device is miniaturized or highly integrated. For example, favorable electrical characteristics can be obtained even when the OS transistor has a channel length or a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Therefore, the OS transistor can be suitably used as a transistor having a short channel length as compared with the Si transistor. Note that the gate length refers to the length of a gate electrode in a direction in which carriers move inside a channel formation region during an operation of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz in a room temperature environment, for example.

As described above, the OS transistor has effects superior to those of the Si transistor, such as a low off-state current and capability of having a short channel length.

### [[Impurity in Metal Oxide]]

Here, the influence of each impurity in the metal oxide (oxide semiconductor) will be described.

When silicon or carbon, which is one of Group 14 elements, is contained in the oxide semiconductor, defect states are formed in the oxide semiconductor. Thus, the concentration of carbon obtained by SIMS in the channel formation region of the oxide semiconductor is set lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, further preferably lower than or equal to 3×10¹⁸ atoms/cm³, and further preferably lower than or equal to 1×10¹⁸ atoms/cm³. The concentration of silicon obtained by SIMS in the channel formation region of the oxide semiconductor is set lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, further preferably lower than or equal to 3×10¹⁸ atoms/cm³, and further preferably lower than or equal to 1×10¹⁸ atoms/cm³.

Furthermore, the oxide semiconductor containing nitrogen easily becomes n-type because electrons serving as carriers are generated and accordingly the carrier concentration is increased. As a result, a transistor using an oxide semiconductor that contains nitrogen as a semiconductor is likely to have normally-on characteristics. Alternatively, when the oxide semiconductor contains nitrogen, trap states are sometimes formed. This might make the electrical characteristics of the transistor unstable. Therefore, the concentration of nitrogen obtained by SIMS in the channel formation region of the oxide semiconductor is set lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, further preferably lower than or equal to 1×10¹⁸ atoms/cm³, and further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor including an oxide semiconductor containing hydrogen is likely to have normally-on characteristics. For this reason, hydrogen in the channel formation region of the oxide semiconductor is preferably reduced as much as possible. Specifically, the concentration of hydrogen obtained by SIMS in the channel formation region of the oxide semiconductor is set lower than 1×10²⁰ atoms/cm³, preferably lower than 5×10¹⁹ atoms/cm³, further preferably lower than 1×10¹⁹ atoms/cm³, further preferably lower than 5×10¹⁸ atoms/cm³, and further preferably lower than 1×10¹⁸ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal obtained by SIMS in the channel formation region of the oxide semiconductor is set lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, the transistor can have stable electrical characteristics.

### [Other Semiconductor Materials]

The oxide semiconductor can be rephrased as a semiconductor layer including a channel formation region of a transistor. A semiconductor material that can be used for the semiconductor layer is not limited to the above-described metal oxides. A semiconductor material that has a band gap (a semiconductor material that is not a zero-gap semiconductor) may be used for the semiconductor layer. For example, a single element semiconductor, a compound semiconductor, or a layered substance (also referred to as an atomic layer substance, a two-dimensional material, or the like) is preferably used as the semiconductor material.

Here, in this specification and the like, the layered substance generally refers to a group of materials having a layered crystal structure. In the layered crystal structure, layers formed by covalent bonding or ionic bonding are stacked with bonding such as the van der Waals force, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. As silicon that can be used for the semiconductor layer, single crystal silicon, polycrystalline silicon, microcrystalline silicon, and amorphous silicon can be given. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered substance contains carbon, nitrogen, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For the semiconductor layer, transition metal chalcogenide functioning as a semiconductor is preferably used, for example. Specific examples of the transition metal chalcogenide which can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the above-described transition metal chalcogenide for the semiconductor layer enables a memory device with a high on-state current to be provided.

Next, an operation example of the memory string 10 is described.

The cell transistor TrC functions as a memory cell. Data is written through injection of charge into the charge accumulation layer (the insulator 62) included in the cell transistor TrC.

The cell transistor TrC operates as a normally-off (enhancement) transistor in the state where Data0 is written, and operates as a normally-on (depletion) transistor in the state where Data1 is written. The selection transistor TrS_1 and the selection transistor TrS_2 always operate as normally-off (enhancement) transistors.

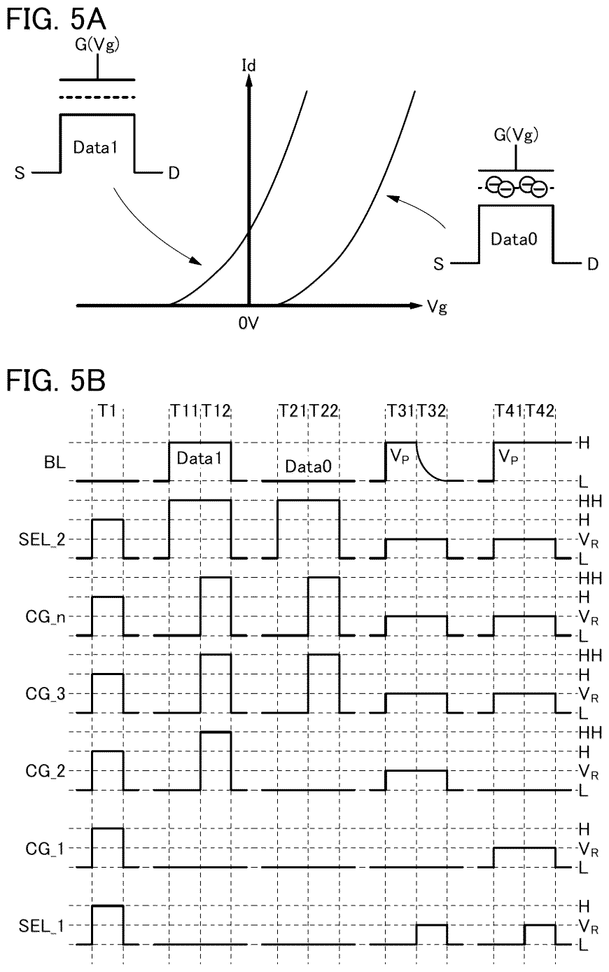

Here, Id-Vg characteristics of the cell transistor TrC are described. FIG. 5A is a diagram showing examples of Id-Vg characteristics of the cell transistor TrC. In FIG. 5A, the horizontal axis represents gate voltage (Vg) and the vertical axis represents drain current (Id).

When the potential of the gate G becomes sufficiently higher than the those of the source S and the drain D by supply of a high voltage to the gate G, electrons are supplied from the semiconductor to the charge accumulation layer through the insulator, and electrons are injected into the charge accumulation layer as in a transistor shown on the right side. At this time, the Id-Vg characteristics indicate the normally-off state. This state is referred to as a state where Data0 is written.

Conversely, when the potentials of the source S and the drain D become sufficiently higher than that of the gate G by supply of a high voltage to the source S and the drain D, electrons injected into the charge accumulation layer are released to the semiconductor through the insulator, and the charge accumulation layer has no electron as in a transistor shown on the left side. At this time, the Id-Vg characteristics indicate the normally-on state. This state is referred to as a state where Data1 is written.

In this manner, the threshold voltage of the cell transistor TrC is changed by controlling the entry and extraction of electrons into and from the charge accumulation layer, whereby data in the memory string is reset, written, and read.

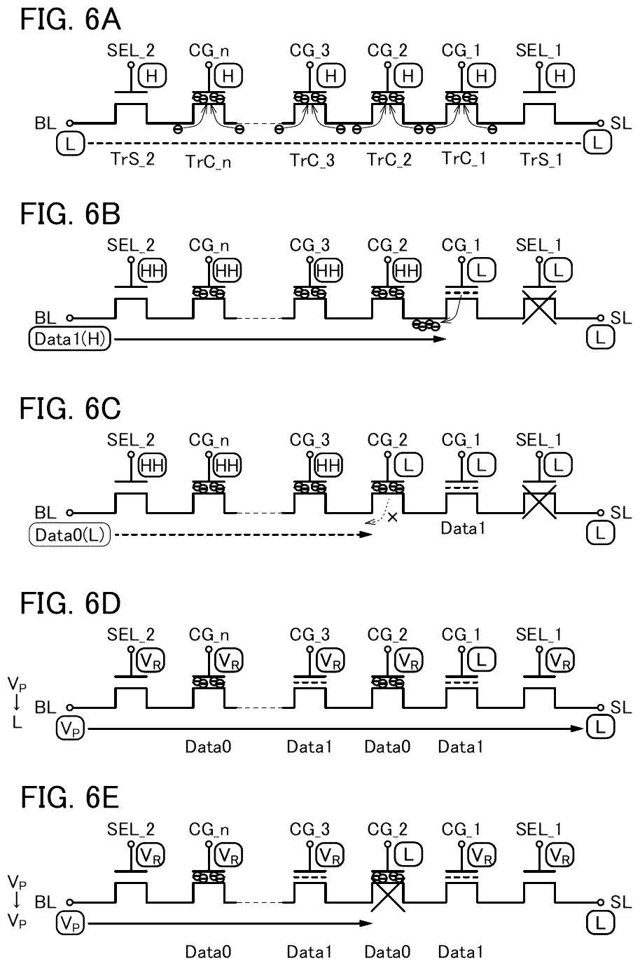

Next, a specific operation example of the memory string illustrated in FIG. 1B is described with reference to a timing chart illustrated in FIG. 5B and diagrams illustrating the operation of the memory string in FIG. 6A to FIG. 6E.

Here, in the operation of the memory string, a low-level potential “L”, a reading potential “V_{R}”, a high-level potential “H”, and a high-level potential “HH” can be used, and are set to “L”< “V_{R}”< “H”< “HH”. In the reading operation, a potential “V_{P}” corresponding to “H” is used for precharging of the bit line BL. The potential of the source line SL is always set to “L”. For “L”, for example, 0 V, a GND potential or the like can be used.

First, data reset of the memory string is described. In the memory string, data of a plurality of cell transistors TrC (memory cells) connected in series can be reset at a time.

In a period T1, the potential of the bit line BL is set to “L”, the potential of a wiring SEL_2 is set to “H”, the potentials of wirings CG_1 to CG_n are set to “H”, and the potential of a wiring SEL_1 is set to “H”. Here, the high-level potential “H” is a potential at which electrons can be extracted into and extracted from the charge accumulation layer and a potential at which a normally-off transistor can be brought into a conduction state.

At this time, the selection transistor TrS_1, the cell transistor TrC, and the selection transistor TrS_2 are in a conduction state. In the cell transistor TrC, electrons are supplied from the semiconductor layer to the charge accumulation layer through the tunnel layer owing to a potential difference between the gate and the source and the drain (see FIG. 6A). Through this operation, data in all the cell transistors TrC (memory cells) is reset.

Next, writing of data is described. Here, an example in which “Data1” and “Data0” are written to the cell transistor TrC_1 and the cell transistor TrC_2, respectively, is described.

In a period T11, the potential of the bit line BL is set to “Data1”, the potential of the wiring SEL_2 is set to “HH”, the potentials of the wirings CG_1 to CG_n are set to “L”, and the potential of the wiring SEL_1 is set to “L”. Here, “Data1” corresponds to data “1”, and “Data1” can be a potential equivalent to a high-level potential “H”, for example. The high-level potential “HH” is a potential at which a normally-off transistor whose source potential is “H” can be brought into a conduction state.

In a period T12, the potential of the bit line BL is set to “Data1”, the potential of the wiring SEL_2 is set to “HH”, the potentials of the wirings CG_2 to CG_n are set to “HH”, the potential of the wiring CG_1 is set to “L”, and the potential of the wiring SEL_1 is set to “L”.

At this time, the selection transistor TrS_2 and the cell transistors TrC_2 to TrC_n are in a conduction state, and the potential “Data1” of the bit line BL is supplied to one of the source and the drain of the cell transistor TrC_1. In the cell transistor TrC_1, electrons are released from the charge accumulation layer to the semiconductor layer through the tunnel layer owing to a potential difference between the gate and one of the source and the drain (see FIG. 6B). This state can be referred to as “Data1” writing to the cell transistor TrC_1.

In a period T21, the potential of the bit line BL is set to “Data0”, the potential of the wiring SEL_2 is set to “HH”, the potentials of the wirings CG_1 to CG_n are set to “L”, and the potential of the wiring SEL_1 is set to “L”. Here, “Data0” corresponds to data “0”, and “Data0” can be a potential equivalent to a low-level potential “L”, for example.

In a period T22, the potential of the bit line BL is set to “Data0”, the potential of the wiring SEL_2 is set to “HH”, the potentials of the wirings CG_3 to CG_n are set to “HH”, the potentials of the wirings CG_1 and CG_2 are set to “L”, and the potential of the wiring SEL_1 is set to “L”.

At this time, the selection transistor TrS_2 and the cell transistors TrC_3 to TrC_n are in a conduction state, and the potential “Data0” of the bit line BL is supplied to one of the source and the drain of the cell transistor TrC_2. In the cell transistor TrC_2, the gate and one of the source and the drain have substantially the same potential; thus, the electrons supplied in the period T1 remain in the charge accumulation layer (see FIG. 6C). This state can be referred to as “Data0” writing to the cell transistor TrC_2.

Next, reading of data is described. Note that when the operation similar to the above is performed, “Data1” and “Data0” are assumed to be written to the cell transistor TrC_3 and to the cell transistor TrC_3, respectively. Here, an example in which “Data1” and “Data0” are read from the cell transistor TrC_1 and the cell transistor TrC_2, respectively, is described.

A potential “L” is supplied to a gate of the cell transistor TrC targeted for reading. In a state where the cell transistor TrC, to which “Data1” is written, is normally on, the transistor is in a conduction state even when a potential supplied to the gate is “L”. In a state where the cell transistor TrC, to which “Data0” is written, is normally off, the transistor is in a non-conduction state when a potential supplied to the gate is “L”.

When all the other transistors are in a conduction state and the cell transistor TrC to be read is in a conduction state, electrical continuity is established between the bit line BL and the source line SL, so that the potential of the precharged bit line BL decreases. Thus, “Data1” or “Data0” can be determined.

In a period T31, the potential of the bit line BL is set to “V_{P}”, the potential of the wiring SEL_2 is set to “V_{R}”, the potentials of the wirings CG_2 to CG_n are set to “V_{R}”, the potential of the wiring CG_1 is set to “L”, and the potential of the wiring SEL_1 is set to “L”. At the end of the period T31, the bit line BL is set to be floating. Here, “V_{P}” is a precharge potential, and can be, for example, a potential equivalent to a first high-level potential “H”. In addition, “V_{R}” is a reading potential, which is a potential higher than or equal to the threshold voltage of a normally-off transistor.

At this time, the selection transistor TrS_2 is in a conduction state. Furthermore, since the cell transistor TrC_1, to which “Data1” is written, is normally on, the cell transistor TrC_1 is in a conduction state even when the potential of the wiring CG_1 is “L”. The cell transistors TrC_2 to TrC_n are in a conduction state because a voltage “V_{R}” higher than or equal to the threshold voltage is applied to the gates of the cell transistors TrC_2 to TrC_n. Note that since the selection transistor TrS_1 is in a non-conduction state, the potential of the bit line BL does not change from “V_{P}”.

In a period T32, the potential of the wiring SEL_2 is set to “V_{R}”, the potentials of the wirings CG_2 to CG_n are set to “V_{R}”, the potential of the wiring CG_1 is set to “L”, and the potential of the wiring SEL_1 is set to “V_{R}”.

At this time, the selection transistor TrS_1 is in a conduction state and the bit line BL and the source line SL are in a conduction state, so that the potential of the bit line BL precharged to “V_{P}” decreases to “L”. Thus, “Data1” can be read from the cell transistor TrC_1 by reading the potential “L” of the bit line BL with the sense amplifier (see FIG. 6D).

In a period T41, the potential of the bit line BL is set to “V_{P}”, the potential of the wiring SEL_2 is set to “V_{R}”, the potentials of the wirings CG_3 to CG_n are set to “V_{R}”, the potential of the wiring CG_2 is set to “L”, the potential of the wiring CG_1 is set to “V_{R}”, and the potential of the wiring SEL_1 is set to “L”. At the end of the period T41, the bit line BL is set to be floating.

At this time, the selection transistor TrS_2 is in a conduction state. Furthermore, since the cell transistor TrC_2, to which “Data0” is written, is normally off, the cell transistor TrC_2 is in a non-conduction state when the potential of the wiring CG_1 is “L”. The cell transistors TrC_1 and TrC_3 to TrC_n are in a conduction state because a voltage “V_{R}” higher than or equal to the threshold voltage is applied to the gates of the cell transistors TrC_1 and TrC_3 to TrC_n. At this time, since the cell transistor TrC_2 and the selection transistor TrS_1 are in a non-conduction state, the potential of the bit line BL does not change from “V_{P}”.

In a period T42, the potential of the wiring SEL_2 is set to “V_{R}”, the potentials of the wirings CG_3 to CG_n are set to “V_{R}”, the potential of the wiring CG_2 is set to “L”, the potential of the wiring CG_1 is set to “V_{R}”, and the potential of the wiring SEL_1 is set to “V_{R}”.

At this time, the selection transistor TrS_1 is in a conduction state, but since the cell transistor TrC_2 is in a non-conduction state, the bit line BL and the source line SL are in a non-conduction state, and the potential of the bit line BL precharged to “V_{P}” does not change. Thus, “Data0” can be read from the cell transistor TrC_1 by reading the potential “V_{P}” of the bit line BL with the sense amplifier (see FIG. 6E).

The above is the description of data reset, writing, and reading in the memory string. In the memory block illustrated in FIG. 2 and FIG. 3 and the like, the wiring SEL_1, the wiring CG, and the wiring SEL_2 are shared by a plurality of memory strings, so that a plurality of memory strings can be operated in parallel.

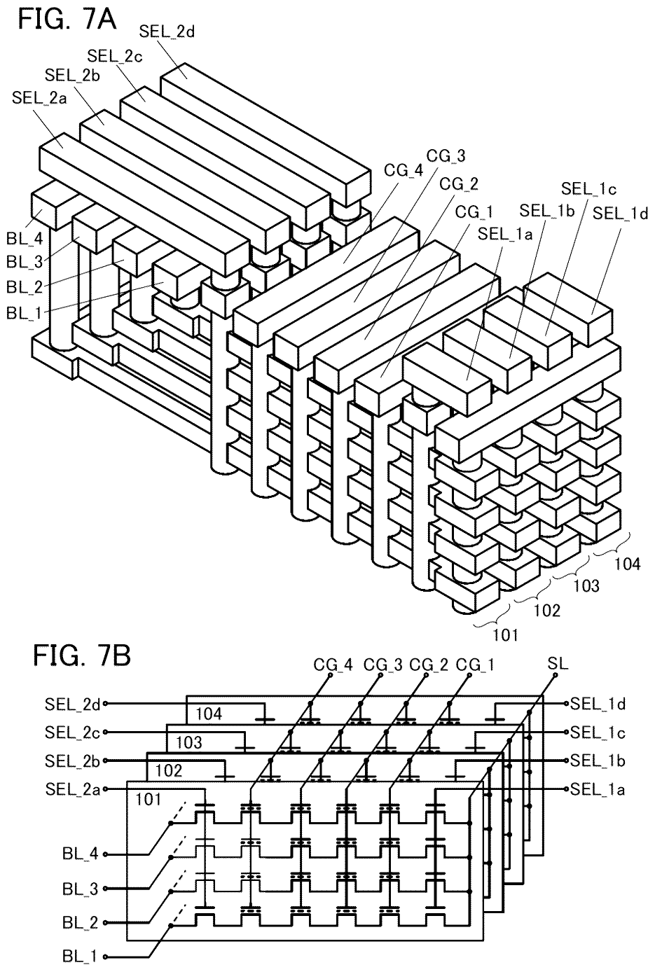

Note that as illustrated in FIG. 7A and FIG. 7B, the memory device of one embodiment of the present invention may include a plurality of memory blocks. FIG. 7A is a perspective view illustrating a memory device including the memory blocks 101 to 104, and FIG. 7B is a circuit diagram illustrating connection between the memory blocks 101 to 104 and wirings.

The memory blocks 101 to 104 can have the same structure, and FIG. 7A and FIG. 7B illustrate an example of a structure in which each memory block includes four memory strings (see FIG. 2 and FIG. 3). When wirings are provided independently for each memory block, the number of wirings is enormous; thus, some wirings are preferably shared by the memory blocks.

FIG. 7A and FIG. 7B illustrate an example in which the wirings CG and the bit lines BL (bit lines BL_1 to BL_4) are shared by the memory blocks. The bit line BL shared by such a plurality of memory blocks can be referred to as a global bit line.

Note that since the bit lines BL are shared, data reset, writing, and reading are performed on each memory block. Thus, wiring connected to the selection transistor TrS is provided for each memory block.

In the memory block 101, a wiring SEL_1a is electrically connected to the selection transistor TrS_1, and a wiring SEL_2a is electrically connected to the selection transistor TrS_2. In the memory block 102, a wiring SEL_1b is electrically connected to the selection transistor TrS_1, and a wiring SEL_2b is electrically connected to the selection transistor TrS_2. In the memory block 103, a wiring SEL_1c is electrically connected to the selection transistor TrS_1, and a wiring SEL_2c is electrically connected to the selection transistor TrS_2. In the memory block 104, a wiring SEL_Id is electrically connected to the selection transistor TrS_1, and a wiring SEL_2d is electrically connected to the selection transistor TrS_2.

With such a structure, the memory device can have large memory capacity and a small number of wirings. Note that the selection transistors may be shared by the memory blocks. In this case, the same number of bit lines BL as that of the memory strings may be provided for each memory block. Although the number of wirings is large, a plurality of memory blocks can be operated in parallel; thus, data can be reset, written, and read at high speed.

The configurations, structures, methods, and the like described in this embodiment can be used in an appropriate combination with any of the configurations, structures, methods, and the like described in the other embodiments and the like.

### Embodiment 2

In this embodiment, a semiconductor device including a memory device according to one embodiment of the present invention will be described.

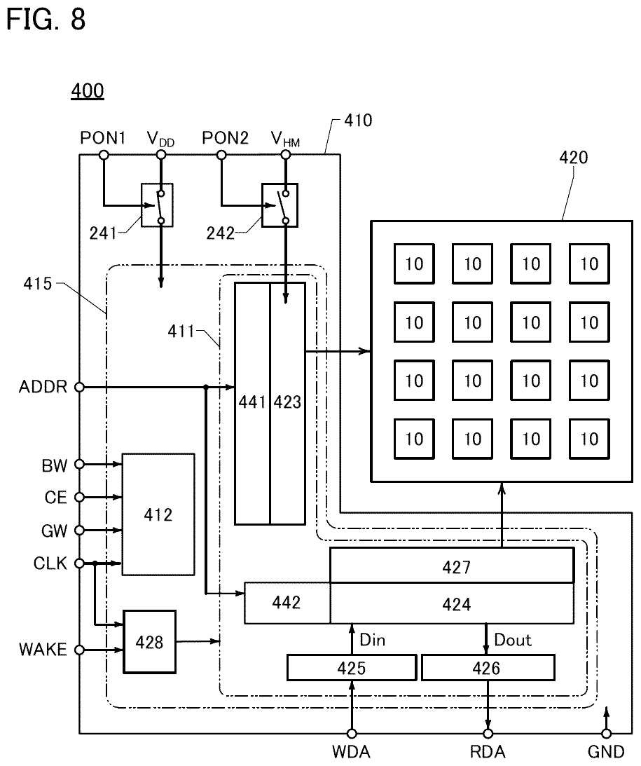

FIG. 8 illustrates a block diagram illustrating a structure example of a semiconductor device 400. The semiconductor device 400 illustrated in FIG. 8 includes a driver circuit 410 and a memory array 420. The memory array 420 includes one or more memory strings 10.

The driver circuit 410 includes a PSW 241 (a power switch), a PSW 242, and a peripheral circuit 415. The peripheral circuit 415 includes a peripheral circuit 411, a control circuit 412, and a voltage generation circuit 428.

In the semiconductor device 400, each circuit, each signal, and each voltage can be appropriately selected as needed. Alternatively, another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

In addition, the signals BW and CE and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signals PON1 and PON2 are power gating control signals. Note that the signals PON1 and PON2 may be generated in the control circuit 412.

The control circuit 412 is a logic circuit having a function of controlling the overall operation of the semiconductor device 400. For example, the control circuit performs logical operation on the signal CE, the signal GW, and the signal BW to determine an operation mode of the semiconductor device 400 (e.g., write operation or read operation). Alternatively, the control circuit 412 generates a control signal for the peripheral circuit 411 so that the operation mode is executed.

The voltage generation circuit 428 has a function of generating negative voltage. WAKE has a function of controlling the input of CLK to the voltage generation circuit 428. For example, when an H-level signal is supplied as WAKE, the signal CLK is input to the voltage generation circuit 428, and the voltage generation circuit 428 generates negative voltage.

The peripheral circuit 411 is a circuit for writing and reading data to and from a memory string 10. The peripheral circuit 411 includes a row decoder 441, a column decoder 442, a row driver 423, a column driver 424, an input circuit 425, an output circuit 426, and a sense amplifier 427.

The row decoder 441 and the column decoder 442 have a function of decoding the signal ADDR. The row decoder 441 is a circuit for specifying a row to be accessed, and the column decoder 442 is a circuit for specifying a column to be accessed. The row driver 423 has a function of selecting the wiring CG specified by the row decoder 441. The column driver 424 has a function of writing data to the memory string 10, a function of reading data from the memory string 10, a function of retaining the read data, and the like.

The input circuit 425 has a function of retaining the signal WDA. Data retained by the input circuit 425 is output to the column driver 424. Data output from the input circuit 425 is data (Din) to be written to the memory string 10. Data (Dout) read from the memory string 10 by the column driver 424 is output to the output circuit 426. The output circuit 426 has a function of retaining Dout. In addition, the output circuit 426 has a function of outputting Dout to the outside of the semiconductor device 400. Data output from the output circuit 426 is the signal RDA.

The PSW 241 has a function of controlling the supply of VDD to the peripheral circuit 415. The PSW 242 has a function of controlling the supply of VHM to the row driver 423. Here, in the semiconductor device 400, high power supply voltage is VDD and low power supply voltage is GND (a ground potential). In addition, VHM is high power supply voltage used to set a word line at a high level and is higher than VDD. The on/off of the PSW 241 is controlled by the signal PON1, and the on/off of the PSW 242 is controlled by the signal PON2. The number of power domains to which VDD is supplied is one in the peripheral circuit 415 in FIG. 8 but can be two or more. In this case, a power switch may be provided for each power domain.

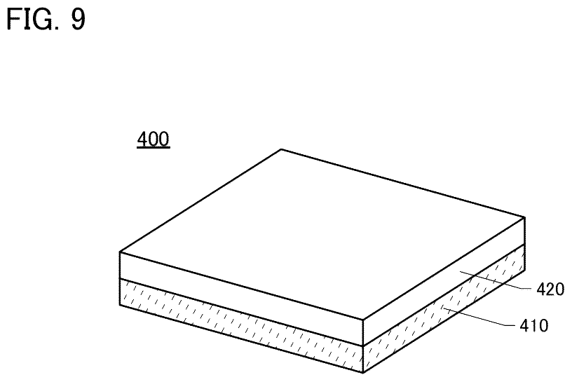

The driver circuit 410 and the memory array 420 that are included in the semiconductor device 400 may be provided on the same plane. In addition, as illustrated in FIG. 9, the driver circuit 410 and the memory array 420 may be provided to overlap with each other. When the driver circuit 410 and the memory array 420 are provided to overlap with each other, the signal transmission distance can be shortened.

In addition, in the semiconductor device 400, an arithmetic processing unit such as a CPU (Central Processing Unit), a GPU (Graphics Processing Unit), and the like may be used for the control circuit 412 included in the driver circuit 410. With the use of the CPU, the GPU, and the like, the semiconductor device 400 that has an arithmetic processing function can be achieved.

The memory string 10 can function as a RAM. Thus, part of the memory array 420 can function as a main memory or a cache memory. The memory string 10 can function as a flash memory. Thus, part of the memory array 420 can function as a flash memory. The semiconductor device 400 according to one embodiment of the present invention can function as a universal memory.

In addition, according to one embodiment of the present invention, functions of a CPU, a cache memory, and a storage can be achieved on the same chip.

The semiconductor device 400 illustrated in FIG. 9 includes the driver circuit 410 including a CPU and a 3D OS NAND memory device according to one embodiment of the present invention in the memory array 420. The 3D OS NAND memory device according to one embodiment of the present invention has a function of a cache memory and a function of a storage.

Note that this embodiment can be combined as appropriate with the other embodiments, Example, and the like described in this specification.

### Embodiment 3

An example of an arithmetic processing unit that can include the memory device described in the above embodiment and the like will be described in this embodiment.

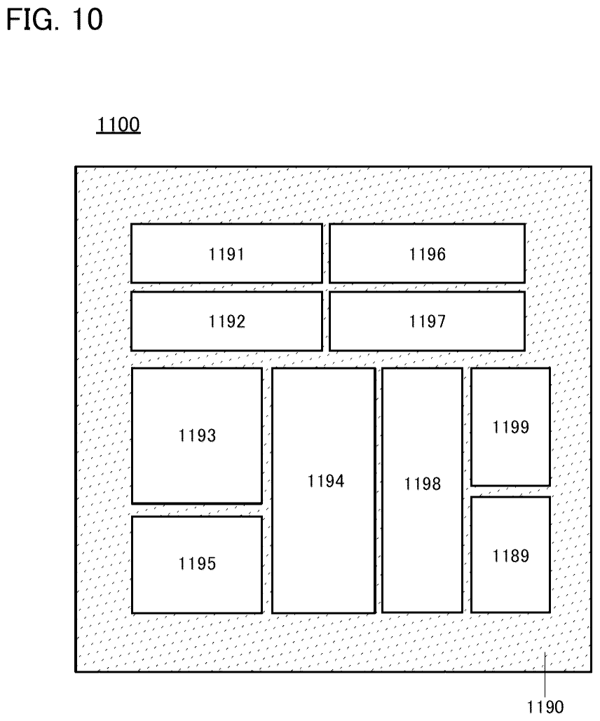

FIG. 10 illustrates a block diagram of a central processing unit 1100. FIG. 10 illustrates a structure example of a CPU as a structure example that can be used for the central processing unit 1100.

The central processing unit 1100 illustrated in FIG. 10 includes, over a substrate 1190, an ALU 1191 (Arithmetic Logic Unit, arithmetic circuit), an ALU controller 1192, an instruction decoder 1193, an interrupt controller 1194, a timing controller 1195, a register 1196, a register controller 1197, a bus interface 1198), a cache 1199, and a cache interface 1189. A semiconductor substrate, an SOI substrate, a glass substrate, or the like is used as the substrate 1190. A rewritable ROM and a ROM interface may be included. In addition, the cache 1199 and the cache interface 1189 may be provided in another chip.

The cache 1199 is connected via the cache interface 1189 to a main memory provided in another chip. The cache interface 1189 has a function of supplying part of data retained in the main memory to the cache 1199. The cache 1199 has a function of retaining the data.

The central processing unit 1100 illustrated in FIG. 10 is only an example with a simplified structure, and depending on the application, a variety of configurations can be employed for the actual central processing unit 1000. For example, the central processing unit may have a GPU-like configuration in which a plurality of cores each including the central processing unit 1100 in FIG. 10 or an arithmetic circuit operate in parallel. In addition, the number of bits that the central processing unit 1100 can process in an internal arithmetic circuit and in a data bus can be 8 bits, 16 bits, 32 bits, 64 bits, or the like, for example.

An instruction that is input to the central processing unit 1100 through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. In addition, while the central processing unit 1100 is executing a program, the interrupt controller 1194 judges an interrupt request from an external input/output device or a peripheral circuit on the basis of its priority or a mask state and processes the request. The register controller 1197 generates an address of the register 1196, and reads and writes data from and to the register 1196 in accordance with the state of the central processing unit 1100.

In addition, the timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator portion for generating an internal clock signal based on a reference clock signal, and supplies the internal clock signal to the above various circuits.

In the central processing unit 1100 illustrated in FIG. 10, a memory device is provided in the register 1196 and the cache 1199. As the memory device, the memory device described in the above embodiment, or the like can be used, for example.

In the central processing unit 1100 illustrated in FIG. 10, the register controller 1197 selects retention operation in the register 1196 in accordance with an instruction from the ALU 1191. That is, the register controller 1197 selects whether data retention by a flip-flop is performed or data retention by a capacitor is performed in the memory cell included in the register 1196. In the case where data retention by the flip-flop is selected, power supply voltage is supplied to the memory cell in the register 1196. In the case where data retention by the capacitor is selected, the data is rewritten into the capacitor, and supply of power supply voltage to the memory cell in the register 1196 can be stopped.

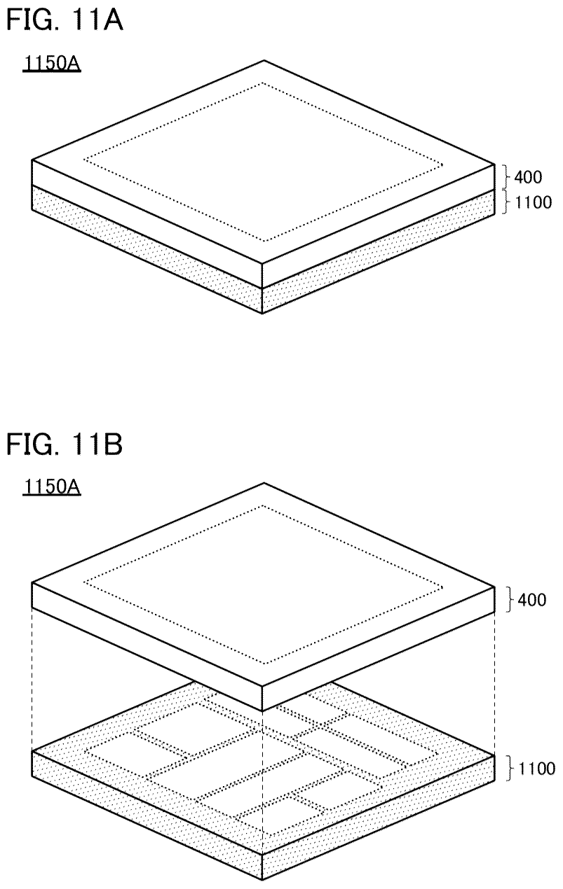

The semiconductor device 400 described in the above embodiment and the central processing unit 1100 can be provided to overlap with each other. FIG. 11A and FIG. 11B illustrate perspective views of a semiconductor device 1150A. The semiconductor device 1150A includes the semiconductor device 400 functioning as a memory device over the central processing unit 1100. The central processing unit 1100 and the semiconductor device 400 have an overlap region. For easy understanding of the structure of the semiconductor device 1150A, the central processing unit 1100 and the semiconductor device 400 are separately illustrated in FIG. 11B.

Overlapping of the semiconductor device 400 and the central processing unit 1100 can shorten the connection distance therebetween. Accordingly, the transmission speed therebetween can be increased. Moreover, since the connection distance is short, power consumption can be reduced.

As described in the above embodiment, when a 3D OS NAND memory device is used as the semiconductor device 400, some or all of a plurality of memory strings 10 included in the semiconductor device 400 can function as a RAM. Thus, the semiconductor device 400 can function as a main memory. The semiconductor device 400 functioning as a main memory is connected to the cache 1199 through the cache interface 1189.

Whether the semiconductor device 400 functions as a main memory (RAM) or storage is controlled by the control circuit 412 illustrated in FIG. 8. The control circuit 412 can make some or all of a plurality of memory strings 10 included in the semiconductor device 400 function as a RAM in accordance with a signal supplied from the central processing unit 1100.

In the semiconductor device 400, some of a plurality of memory strings 10 can function as a RAM, and the other of the memory strings 10 can function as storage. When a 3D OS NAND memory device is used as the semiconductor device 400, the semiconductor device 400 can have the function of the cache, the function of the main memory, and the function of the storage together. The semiconductor device 400 according to one embodiment of the present invention can function as a universal memory, for example.

In the case where the semiconductor device 400 is used as a main memory, the memory capacity can be increased or decreased as needed. In the case where the semiconductor device 400 is used as a cache, the memory capacity can be increased or decreased as needed.

The control circuit 412 illustrated in FIG. 8 may have a function of performing error detection and correction (ECC: also referred to as Error Check and Correct) when data is transferred or duplicated between a region functioning as the storage and a region functioning as the main memory in the semiconductor device 400. The control circuit 412 may have a function of performing ECC when data is transferred or duplicated between the cache 1199 and the region of the semiconductor device 400 functioning as a main memory.

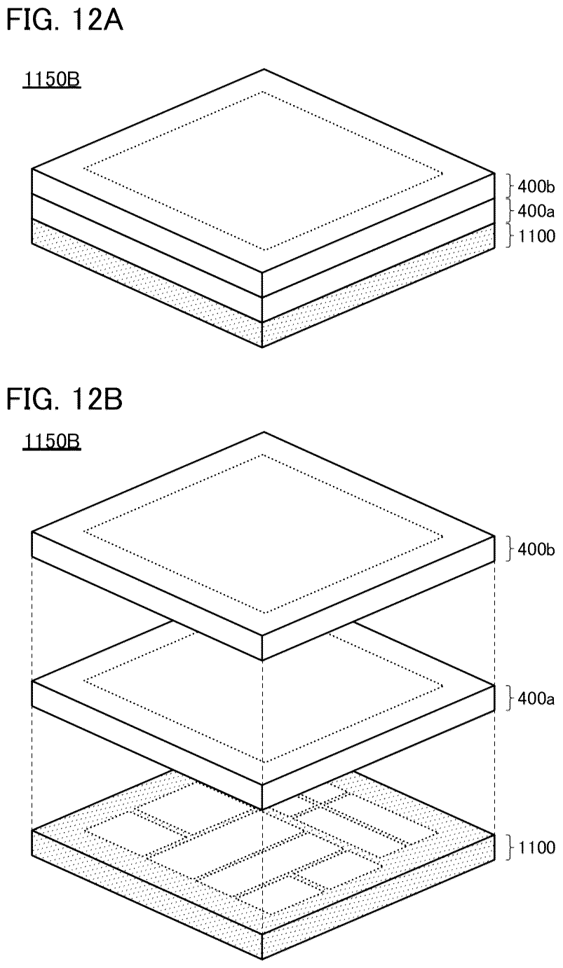

A plurality of semiconductor devices 400 may be provided to overlap with the central processing unit 1100. FIG. 12A and FIG. 12B illustrate perspective views of a semiconductor device 1150B. The semiconductor device 1150B includes a semiconductor device 400a and a semiconductor device 400b over the central processing unit 1100. The central processing unit 1100, the semiconductor device 400a, and the semiconductor device 400b have an overlap region. For easy understanding of the structure of the semiconductor device 1150B, the central processing unit 1100, the semiconductor device 400a, and the semiconductor device 400b are separately illustrated in FIG. 12B.

The semiconductor device 400a and the semiconductor device 400b function as memory devices. For example, a NOR memory device may be used for one of the semiconductor device 400a and the semiconductor device 400b, and a NAND memory device may be used for the other thereof. Both the semiconductor device 400a and the semiconductor device 400b may be NAND memory devices. Examples of the NOR memory device include a DRAM, an SRAM, and the like. A NOR memory device can operate at higher speed than a NAND memory device; thus, for example, part of the semiconductor device 400a can also be used as the main memory and/or the cache 1199. Note that the stacking order of the semiconductor device 400a and the semiconductor device 400b may be reverse.

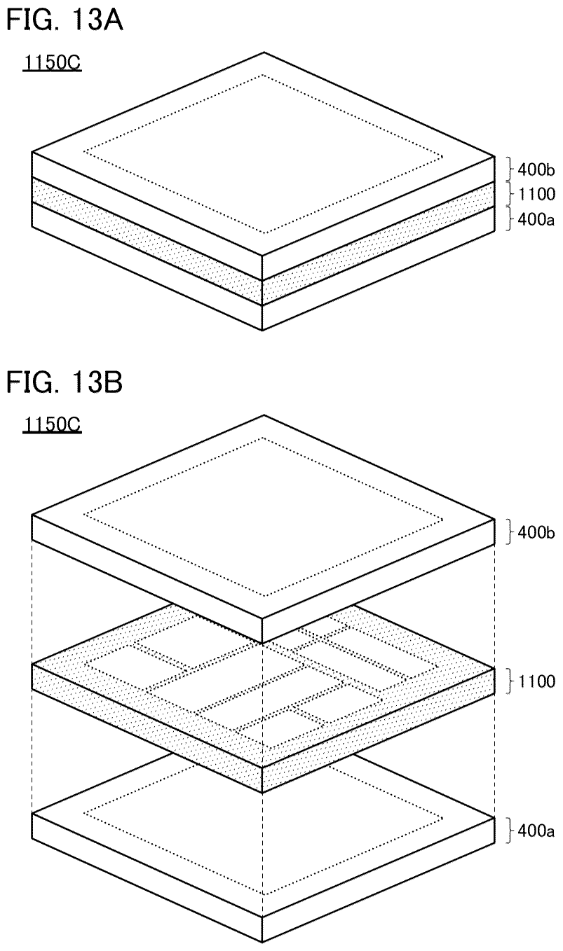

FIG. 13A and FIG. 13B illustrate perspective views of a semiconductor device 1150C. The semiconductor device 1150C has a structure in which the central processing unit 1100 is sandwiched between the semiconductor device 400a and the semiconductor device 400b. The central processing unit 1100, the semiconductor device 400a, and the semiconductor device 400b have an overlap region. For easy understanding of the structure of the semiconductor device 1150C, the central processing unit 1100, the semiconductor device 400a, and the semiconductor device 400b are separately illustrated in FIG. 13B.

With the structure of the semiconductor device 1150C, the transmission speed between the semiconductor device 400a and the central processing unit 1100 and the transmission speed between the semiconductor device 400b and the central processing unit 1100 can be both increased. Moreover, power consumption can be reduced compared to the semiconductor device 1150B.

Note that this embodiment can be combined as appropriate with the other embodiments, Example, and the like described in this specification.

### Embodiment 4

In this embodiment, application examples of the memory device according to one embodiment of the present invention will be described.

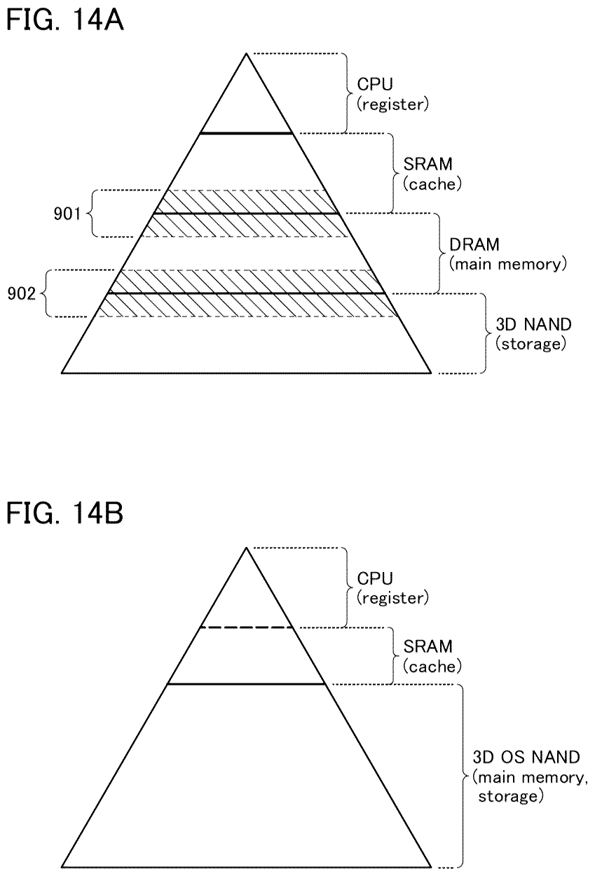

In general, a variety of memory devices are used in semiconductor devices such as computers depending on the application. FIG. 14A illustrates the hierarchy of a variety of memory devices used in a semiconductor device. The memory devices at the upper levels require higher operation speed, and the memory devices at the lower levels require larger memory capacity and higher memory density. In FIG. 14A, sequentially from the top level, a memory included as a register in an arithmetic processing unit such as a CPU, an SRAM (Static Random Access Memory), a DRAM (Dynamic Random Access Memory), and a 3D NAND memory are shown.

A memory included as a register in an arithmetic processing unit such as a CPU is used for temporary storage of arithmetic operation results, for example, and thus is very frequently accessed by the arithmetic processing unit. Accordingly, high operating speed is required rather than the memory capacity. In addition, the register also has a function of retaining setting information of the arithmetic processing unit, for example.

An SRAM is used for a cache, for example. The cache has a function of retaining the copy of part of data retained in a main memory. By duplicating data that is frequently used and retaining the copy of the data in the cache, the access speed to the data can be increased. The cache needs smaller memory capacity than the main memory but higher operation speed than the main memory. In addition, data that is rewritten in the cache is duplicated, and the duplicated data is supplied to the main memory.

A DRAM is used for the main memory, for example. The main memory has a function of retaining a program or data that is read from a storage. The memory density of a DRAM is approximately 0.1 to 0.3 Gbit/mm².

A 3D NAND memory is used for storage, for example. The storage has a function of retaining data that needs to be retained for a long time and a variety of programs used in an arithmetic processing unit, for example. Therefore, the storage needs large memory capacity and high memory density rather than operation speed. The memory density of a memory device used for the storage is approximately 0.6 to 6.0 Gbit/mm².

The memory device according to one embodiment of the present invention operates at high speed and can retain data for a long time. The memory device according to one embodiment of the present invention can be favorably used as a memory device positioned in a boundary region 901 including both a level where the cache is positioned and a level where the main memory is positioned. In addition, the memory device according to one embodiment of the present invention can be favorably used as a memory device positioned in a boundary region 902 including both the level where the main memory is positioned and a level where the storage is positioned.

In addition, the memory device according to one embodiment of the present invention can be favorably used at both the level where the main memory is positioned and the level where the storage is positioned. Furthermore, the memory device according to one embodiment of the present invention can be favorably used at the level where the cache is positioned. FIG. 14B illustrates the hierarchy of a variety of memory devices different from that in FIG. 14A.

FIG. 14B shows, sequentially from the top level, a memory included as a register in an arithmetic processing unit such as a CPU, an SRAM used as a cache, and a 3D OS NAND memory. The 3D OS NAND memory can be used as a cache, a main memory, and storage. Note that when a high-speed memory of 1 GHz or higher is required as a cache, the cache is included in an arithmetic processing unit such as a CPU.

The memory device according to one embodiment of the present invention can be applied to, for example, memory devices of a variety of electronic devices (e.g., information terminals, computers, smartphones, e-book readers, digital still cameras, video cameras, video recording/reproducing devices, navigation systems, game machines, and the like). In addition, the memory device can also be used for image sensors, IoT (Internet of Things), healthcare-related devices, and the like. Note that here, the computers refer to tablet computers, laptop computers, desktop computers, and large computers such as server systems.

Note that this embodiment can be combined as appropriate with the other embodiments, Example, and the like described in this specification.

### Embodiment 5

This embodiment will describe an electronic component, an electronic device, a large computer, space equipment, and a data center (also referred to as a DC) in which the memory device or the semiconductor device described in the above embodiment can be used. Electronic components, electronic devices, a large computer, space equipment, and a data center in which the memory device of one embodiment of the present invention is used are effective in improving performance, e.g., reducing power consumption.

### [Electronic Component]

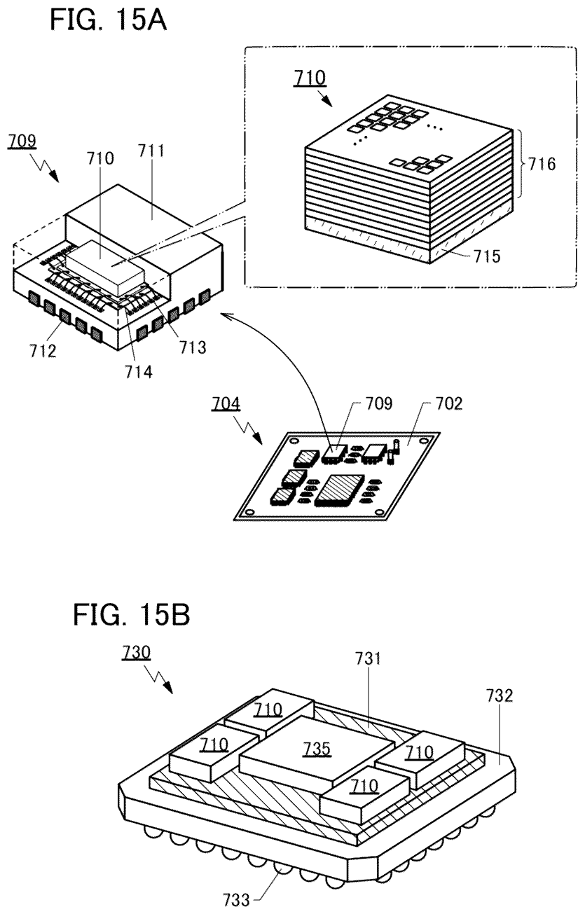

FIG. 15A is a perspective view of a substrate (a mounting board 704) mounted with an electronic component 709. The electronic component 709 illustrated in FIG. 15A includes a memory device 710 in a mold 711. FIG. 15A omits illustrations of some parts to show the inside of the electronic component 709. The electronic component 709 includes a land 712 outside the mold 711. The land 712 is electrically connected to an electrode pad 713, and the electrode pad 713 is electrically connected to the memory device 710 through a wire 714. The electronic component 709 is mounted on a printed circuit board 702, for example. A plurality of such electronic components are combined and electrically connected to each other on the printed circuit board 702, which forms the mounting board 704.

The memory device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a TSV (Through Silicon Via) and a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as a TSV is employed; thus, the number of connection pins can be increased. An increase in the number of connection pins enables parallel operations, which can increase the bandwidth of the memory (also referred to as a memory bandwidth).

It is preferable that a plurality of the memory cell arrays included in the memory layer 716 be formed using OS transistors and be monolithically stacked. The monolithic stacked-layer structure of a plurality of the memory cell arrays can improve the bandwidth of the memory and/or the access latency of the memory. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The memory device 710 may be called a die. In this specification and the like, a die refers to each of chip pieces obtained by dividing a circuit pattern formed on a circular substrate (also referred to as a wafer) or the like into dice in the manufacturing process of a semiconductor chip, for example. Examples of a semiconductor material that can be used for a die include silicon (Si), silicon carbide (SiC), and gallium nitride (GaN). A die obtained from a silicon substrate (also referred to as a silicon wafer) may be referred to as a silicon die, for example.

FIG. 15B is a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of memory devices 710 are provided on the interposer 731.

The electronic component 730 using the memory devices 710 as a high bandwidth memory (HBM) is shown as an example. As the semiconductor device 735, an integrated circuit such as a CPU (Central Processing Unit), a GPU (Graphics Processing Unit), or an FPGA (Field Programmable Gate Array) can be used.

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. A plurality of wirings are provided in a single layer or multiple layers. In addition, the interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which a HBM is mounted requires minute and densely formed wirings. For this reason, a silicon interposer is preferably used as the interposer on which a HBM is mounted.

In addition, in a SiP, an MCM, and the like each using a silicon interposer, a decrease in reliability due to a difference in an expansion coefficient between an integrated circuit and the interposer does not easily occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using a TSV and monolithically stacked memory cell arrays may be employed.

A heat sink (a radiator plate) may be provided to overlap with the electronic component 730. In the case of providing a heat sink, the heights of integrated circuits provided on the interposer 731 are preferably equal to each other. In the electronic component 730 of this embodiment, the levels of the memory device 710 and the semiconductor device 735 are preferably equal to each other, for example.

To mount the electronic component 730 on another substrate, an electrode 733 may be provided on a bottom portion of the package substrate 732. FIG. 15B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### [Electronic Device]

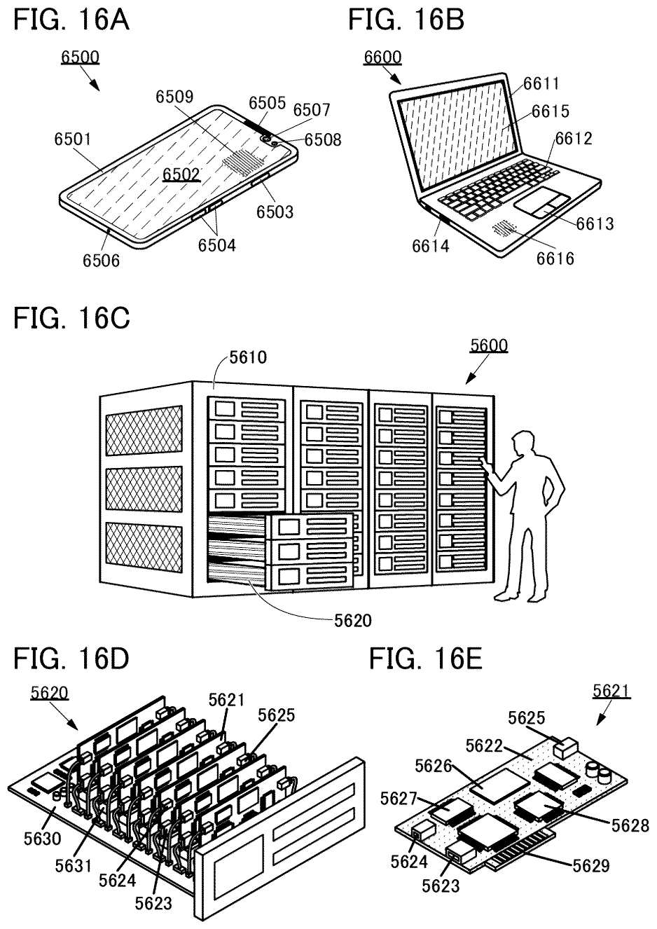

FIG. 16A is a perspective view of an electronic device 6500. The electronic device 6500 illustrated in FIG. 16A is a portable information terminal that can be used for a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that the control device 6509 includes one or more selected from a CPU, a GPU, and a memory device, for example. The memory device of one embodiment of the present invention can be employed for the display portion 6502, the control device 6509, or the like.

An electronic device 6600 illustrated in FIG. 16B is an information terminal that can be used as a notebook personal computer. The electronic device 6600 includes a housing 6611, a keyboard 6612, a pointing device 6613, an external connection port 6614, a display portion 6615, a control device 6616, and the like. Note that the control device 6616 includes one or more selected from a CPU, a GPU, and a memory device, for example. The memory device of one embodiment of the present invention can be employed for the display portion 6615, the control device 6616, or the like. Note that the memory device of one embodiment of the present invention is preferably used for the control device 6509 and the control device 6616, in which case power consumption can be reduced.

### [Large Computer]

FIG. 16C is a perspective view of a large computer 5600. In the large computer 5600 illustrated in FIG. 16C, a plurality of rack mount computers 5620 are stored in a rack 5610. Note that the large computer 5600 may be referred to as a supercomputer.

The computer 5620 can have a structure in a perspective view illustrated in FIG. 16D, for example. In FIG. 16D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 16E is an example of a processing board provided with a CPU, a GPU, a storage device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. FIG. 16E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. The electronic component 709 can be used for the semiconductor device 5628, for example.

The large computer 5600 can also function as a parallel computer. When the large computer 5600 is used as a parallel computer, large-scale computation necessary for artificial intelligence learning and inference can be performed, for example.

### [Space Equipment]

The memory device of one embodiment of the present invention can be suitably used for space equipment such as equipment that processes and stores information.

The memory device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

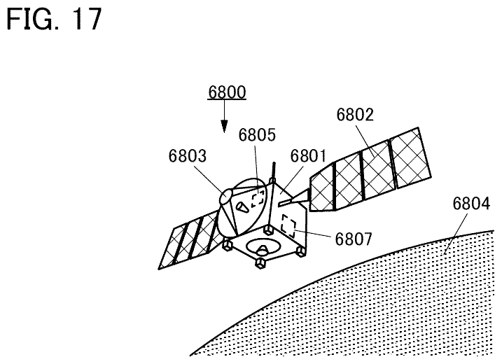

FIG. 17 illustrates an artificial satellite 6800 as an example of space equipment. The artificial satellite 6800 includes a body 6801, a solar panel 6802, an antenna 6803, a secondary battery 6805, and a control device 6807. Note that in FIG. 17, a planet 6804 in outer space is illustrated as an example. Note that outer space refers to, for example, space at an altitude greater than or equal to 100 km, and outer space described in this specification may include thermosphere, mesosphere, and stratosphere.

Although not illustrated in FIG. 17, the secondary battery 6805 may be provided with a battery management system (also referred to as a BMS) or a battery control circuit. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for an operation of the artificial satellite 6800 is generated. However, for example, in the situation where the solar panel is not irradiated with sunlight or the amount of sunlight with which the solar panel is irradiated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed with one or more selected from a CPU, a GPU, and a memory device, for example. Note that the memory device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The memory device of one embodiment of the present invention can be suitably used for space equipment such as a spacecraft, a space capsule, or a space probe, for example.

As described above, the OS transistor has excellent effects of achieving a wide memory bandwidth and being highly resistant to radiation as compared with the Si transistor.

### [Data Center]

The memory device of one embodiment of the present invention can be suitably used for a storage system in a data center, for example. Long-term data management, such as a guarantee for data immutability, is required for the data center. The long-term management of data needs an increase in building size owing to installation of storages and servers for storing an enormous amount of data, stable electric power for data retention, cooling equipment necessary for data retention, and the like.

With the use of the memory device of one embodiment of the present invention for the storage system used in the data center, electric power required for data retention can be reduced and the size of a memory device retaining data can be downsized. Thus, downsizing of the storage system, downsizing of the power supply for retaining data, downscaling of the cooling equipment, and the like can be achieved. This can reduce the space of the data center.

Since the memory device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the memory device of one embodiment of the present invention enables a data center that operates stably even in a high-temperature environment. Thus, the reliability of the data center can be increased.

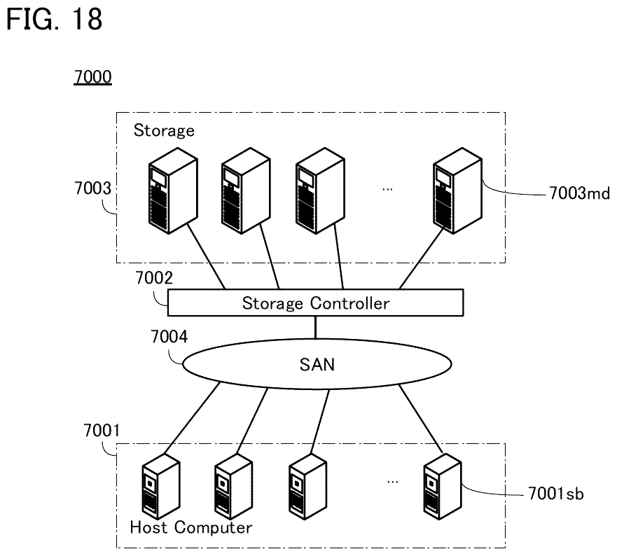

FIG. 18 illustrates a storage system that can be used in a data center. A storage system 7000 illustrated in FIG. 18 includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated mode, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is considerably longer than the data access speed of a DRAM that can be used as a cache memory in a storage. In the storage system, in order to solve the problem of low access speed of the storage 7003, a cache memory is usually provided in a storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the memory device of one embodiment of the present invention for one or more selected from an electronic component, an electronic device, a large computer, space equipment, and a data center will produce an effect of reducing power consumption. While the demand for energy is expected to increase with higher performance or higher integration of memory devices, the emission amount of greenhouse effect gases typified by carbon dioxide (CO₂) can be reduced with use of the memory device of one embodiment of the present invention. The memory device of one embodiment of the present invention can be effectively used as one of the global warming countermeasures because of its low power consumption.

The configurations, structures, methods, and the like described in this embodiment can be used in an appropriate combination with any of the configurations, structures, methods, and the like described in the other embodiments and the like.

### REFERENCE NUMERALS

BL_1: bit line, BL_2: bit line, BL_3: bit line, BL_4: bit line, BL: bit line, CG_1: wiring, CG_2: wiring, CG_3: wiring, CG_n: wiring, CG: wiring, SEL_1: wiring, SEL_1a: wiring, SEL_1b: wiring, SEL_1c: wiring, SEL_Id: wiring, SEL_2: wiring, SEL_2a: wiring, SEL_2b: wiring, SEL_2c: wiring, SEL_2d: wiring, SL: source line, TrC_1: cell transistor, TrC_2: cell transistor, TrC_3: cell transistor, TrC: cell transistor, TrS_1: selection transistor, TrS_2: selection transistor, TrS: selection transistor, 10_1: memory string, 10_2: memory string, 10_3: memory string, 10_4: memory string, 10: memory string, 20_1: conductor, 20_2: conductor, 20_3: conductor, 20_4: conductor, 20: conductor, 21_1: insulator, 21_5: insulator, 21: insulator, 22: insulator, 30_1: structure body, 30_2: structure body, 30: structure body, 31: opening, 40_1: structure body, 40_4: structure body, 40: structure body, 41: opening, 50: plug, 60c: insulator, 60s: insulator, 60: insulator, 61: insulator, 62: insulator, 63: insulator, 70c: oxide semiconductor, 70s: oxide semiconductor, 70: oxide semiconductor, 80c: conductor, 80s: conductor, 80: conductor, 101: memory block, 102: memory block, 103: memory block, 104: memory block, 241: PSW, 242: PSW, 400a: semiconductor device, 400b: semiconductor device, 400: semiconductor device, 410: driver circuit, 411: peripheral circuit, 412: control circuit, 415: peripheral circuit, 420: memory array, 423: row driver, 424: column driver, 425: input circuit, 426: output circuit, 427: sense amplifier, 428: voltage generation circuit, 441: row decoder, 442: column decoder, 702: printed circuit board, 704: mounting board, 709: electronic component, 710: memory device, 711: mold, 712: land, 713: electrode pad, 714: wire, 715: driver circuit layer, 716: memory layer, 730: electronic component, 731: interposer, 732: package substrate, 733: electrode, 735: semiconductor device, 901: boundary region, 902: boundary region, 1100: central processing unit, 1150A: semiconductor device, 1150B: semiconductor device, 1150C: semiconductor device, 1189: cache interface, 1190: substrate, 1191: ALU, 1192: ALU controller, 1193: instruction decoder, 1194: interrupt controller, 1195: timing controller, 1196: register, 1197: register controller, 1198: bus interface, 1199: cache, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: mother board, 5631: slot, 6500: electronic device, 6501: housing, 6502: display portion, 6503: power source button, 6504: button, 6505: speaker, 6506: microphone, 6507: camera, 6508: light source, 6509: control device, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001sb: server, 7001: host, 7002: storage control circuit, 7003md: memory device, 7003: storage

1. A memory device comprising:
a memory string in which a first transistor, a plurality of second transistors, and a third transistor are connected in series in this order,
wherein the first transistor, the plurality of second transistors, and the third transistor each comprise a structure body having a cylindrical shape,
wherein the structure body has a structure in which an oxide semiconductor, an insulator, and a first conductor are concentrically provided in this order in an inward direction from a side surface of the structure body,
wherein the structure body comprises a first region on the side surface and a second region on a side opposite to the first region,
wherein a second conductor is provided in contact with the first region and a third conductor is provided in contact with the second region,
wherein in each of the first transistor, the plurality of second transistors, and the third transistor:
the first conductor is configured to serve as a gate electrode;
the second conductor is configured to serve as one of a source electrode and a drain electrode; and
the third conductor is configured to serve as the other of the source electrode and the drain electrode, and
wherein the structure body of each of the plurality of second transistors further comprises a charge accumulation layer between the oxide semiconductor and the first conductor.

2. The memory device according to claim 1,
wherein the one of the source electrode and the drain electrode of the first transistor is electrically connected to a source line, and the one of the source electrode and the drain electrode of the third transistor is electrically connected to a bit line.

3. The memory device according to claim 1, comprising:
a memory block in which a plurality of the memory strings are stacked in a direction perpendicular to a longitudinal direction of the memory string.

4. The memory device according to claim 3, comprising:
a plurality of the memory blocks.

5. The memory device according to claim 1,
wherein the charge accumulation layer comprises silicon nitride.

6. The memory device according to claim 1,
wherein the oxide semiconductor comprises at least one of indium and zinc.

7. An electronic device comprising:
the memory device according to claim 6; and
at least one of a camera and a display portion.
